(19) United States
(12) Patent Application Publication
(10) Pub. No.: US 2026/0353895 A1
(43) Pub. Date: Nov. 5, 2026

(54) DISPLAY APPARATUS AND ELECTRONIC DEVICE

(71) Applicant: SONY SEMICONDUCTOR SOLUTIONS CORPORATION, KANAGAWA (JP)

(72) Inventors: RYOMA MURAOKA, KANAGAWA (JP); AKITSUNA TAKAGI, KANAGAWA (JP); HIDEYUKI TANAKA, KANAGAWA (JP); KEIICHI YAGI, KANAGAWA (JP); CHUGEN HAMACHI, KANAGAWA (JP)

(21) Appl. No.: 19/488,262

(22) PCT Filed: May 14, 2024
(86) PCT No.: PCT/JP2024/017708

§ 371 Date: Nov. 26, 2025

(30) Foreign Application Priority Data
Jun. 7, 2023 (JP) 2023-094283

(51) Int. Cl. H10H 29/85; H10H 29/851

(52) U.S. Cl. CPC H10H 29/8517; H10H 29/8514

(57) ABSTRACT

Provided is a display apparatus capable of improving viewing angle characteristics.

The display apparatus includes a plurality of first pixels capable of emitting light of a first color and a plurality of second pixels capable of emitting light of a second color. The plurality of second pixels constitutes a plurality of columns. The column of the second pixels includes: a plurality of first light emitting elements arranged in a column direction of the column of the second pixels; a first filter portion provided above the plurality of first light emitting elements and having a second color; and a plurality of second filter portions provided above the plurality of first light emitting elements and at respective boundary portions between the second pixels adjacent in the column direction and having a color different from the second color.

### TECHNICAL FIELD

The present disclosure relates to a display apparatus and an electronic device including the display apparatus.

### BACKGROUND ART

In recent years, there has been a demand for a technique for improving viewing angle characteristics of a display apparatus. For example, Patent Document 1 describes that a display apparatus in which a first subpixel, a second subpixel, and a third subpixel are arranged in a square shape has a problem that viewing angle characteristics are deteriorated due to a difference in aperture ratio. Furthermore, in order to solve this problem, Patent Document 1 describes that the viewing angle of the third subpixel is limited by a black matrix (light shielding portion).

### CITATION LIST

### Patent Document

Patent Document 1: Japanese Patent Application Laid-Open No. 2015-146304

### SUMMARY OF THE INVENTION

### Problems to be Solved by the Invention

As described above, in recent years, a technique for improving viewing angle characteristics of a display apparatus has been required.

An object of the present disclosure relates to a display apparatus capable of improving viewing angle characteristics and an electronic device including the display apparatus.

### Solutions to Problems

In order to solve the above problem, a display apparatus according to a first aspect of the present disclosure includes:
a plurality of first pixels capable of emitting light of a first color; and
a plurality of second pixels capable of emitting light of a second color,
in which
the plurality of second pixels constitutes a plurality of columns, and
a column of the second pixels includes:
a plurality of first light emitting elements arranged in a column direction of a column of the second pixels;
a first filter portion provided above the plurality of first light emitting elements and having the second color; and
a plurality of second filter portions provided above the plurality of first light emitting elements and at respective boundary portions between the second pixels adjacent in the column direction, the plurality of second filter portions having a color different from the second color.

A display apparatus according to a second aspect of the present disclosure includes:
a plurality of first pixels capable of emitting light of a first color; and
a plurality of second pixels capable of emitting light of a second color,
in which
the plurality of second pixels constitutes a plurality of columns, and
a column of the second pixels includes:
a plurality of first light emitting elements arranged in a column direction of a column of the second pixels;
a color conversion section provided above the plurality of first light emitting elements and capable of converting light emitted from the plurality of first light emitting elements into light of the second color; and
a plurality of filter portions provided above the plurality of first light emitting elements and at respective boundary portions between the second pixels adjacent in the column direction, the plurality of filter portions having a color different from the second color.

An electronic device according to an aspect of the present disclosure includes the display apparatus according to the first aspect of the present disclosure or the display apparatus according to the second aspect of the present disclosure.

### BRIEF DESCRIPTION OF DRAWINGS

FIG. 1 is a plan view of subpixels arranged in a stripe array.

FIG. 2 is a plan view of a display apparatus according to a first embodiment.

FIG. 3 is an enlarged plan view illustrating a part of an effective pixel region in FIG. 2.

FIG. 4 is a cross-sectional view taken along line IV-IV of FIG. 3.

FIG. 5 is a cross-sectional view taken along line V-V of FIG. 3.

FIG. 6 is a cross-sectional view taken along line VI-VI of FIG. 3.

FIG. 7 is a plan view of subpixels arranged in a square manner.

FIG. 8 is an enlarged plan view illustrating a part of an effective pixel region of a display apparatus according to a second embodiment.

FIG. 9 is a cross-sectional view taken along line IX-IX of FIG. 8.

FIG. 10 is a cross-sectional view taken along line X-X of FIG. 8.

FIG. 11 is an enlarged plan view illustrating a part of an effective pixel region.

FIG. 12 is a cross-sectional view taken along line XII-XII of FIG. 11.

FIG. 13 is an enlarged plan view illustrating a part of an effective pixel region.

FIG. 14 is a cross-sectional view taken along line XIV-XIV of FIG. 13.

FIG. 15 is an enlarged plan view illustrating a part of an effective pixel region.

FIG. 16 is an enlarged plan view illustrating a part of an effective pixel region.

FIG. 17 is an enlarged cross-sectional view of an effective pixel region.

FIG. 18 is an enlarged cross-sectional view of an effective pixel region.

FIG. 19 is an enlarged cross-sectional view of an effective pixel region.

FIG. 20 is an enlarged cross-sectional view of an effective pixel region.

FIG. 21 is an enlarged cross-sectional view of an effective pixel region.

FIG. 22 is an enlarged cross-sectional view (XZ cross-sectional view) of an effective pixel region.

FIG. 23 is an enlarged cross-sectional view (YZ cross-sectional view) of an effective pixel region.

FIG. 24A is a schematic diagram of an analysis model of simulation 1. FIG. 24B is a schematic diagram of an analysis model of simulation 2. FIG. 24C is a schematic diagram of an analysis model of simulation 3. FIG. 24D is a schematic diagram of an analysis model of simulation 4.

FIG. 25 is a graph illustrating a result of simulation 1 to 4.

FIGS. 26A, 26B, and 26C are conceptual diagrams for explaining a relationship among a normal line LN passing through the center of the light emitting section, a normal line LN′ passing through the center of the lens member, and a normal line LN″ passing through the center of the wavelength selection section, respectively.

FIG. 27 is a conceptual diagram for explaining a relationship among a normal line LN passing through the center of the light emitting section, a normal line LN′ passing through the center of the lens member, and a normal line LN″ passing through the center of the wavelength selection section.

FIGS. 28A and 28B are conceptual diagrams for explaining a relationship among a normal line LN passing through the center of the light emitting section, a normal line LN′ passing through the center of the lens member, and a normal line LN″ passing through the center of the wavelength selection section, respectively.

FIG. 29 is a conceptual diagram for explaining a relationship among a normal line LN passing through the center of the light emitting section, a normal line LN′ passing through the center of the lens member, and a normal line LN″ passing through the center of the wavelength selection section.

FIG. 30A is a schematic cross-sectional view for explaining a first example of the resonator structure. FIG. 30B is a schematic cross-sectional view for explaining a second example of the resonator structure.

FIG. 31A is a schematic cross-sectional view for explaining a third example of the resonator structure. FIG. 31B is a schematic cross-sectional view for explaining a fourth example of the resonator structure.

FIG. 32A is a schematic cross-sectional view for explaining a fifth example of the resonator structure. FIG. 32B is a schematic cross-sectional view for explaining a sixth example of the resonator structure.

FIG. 33 is a schematic cross-sectional view for explaining a seventh example of the resonator structure.

FIG. 34A is a front view of a digital still camera. FIG. 34B is a rear view of the digital still camera.

FIG. 35 is a perspective view of a head-mounted display.

FIG. 36 is a perspective view of a television apparatus.

FIG. 37 is a perspective view of a see-through head-mounted display.

FIG. 38 is a perspective view of a smartphone.

FIG. 39A is a diagram illustrating an internal state of a vehicle from a rear side to a front side of the vehicle. FIG. 39B is a diagram illustrating an internal state of a vehicle from an oblique rear side to an oblique front side of the vehicle.

### MODE FOR CARRYING OUT THE INVENTION

Embodiments and the like of the present disclosure will be described in the following order.
1 General Description of Display Apparatuses According to First and Second Aspects of Present Disclosure
2 First Embodiment (Example of Display Apparatus)
3 Second Embodiment (Example of Display Apparatus)
4 Modifications
5 Simulation
6 Relationship Between Normal Lines Passing Through Centers of Light Emitting Section, Lens Member, and Wavelength Selection Section
7 Example of Resonator Structure
8 Application Example (Example of Electronic Device)

The embodiments and the like described below are preferred specific examples of the present disclosure, and the content of the present disclosure is not limited to these embodiments and the like. Note that, in the following description, components having substantially the same functional configuration are denoted by the same reference signs, and redundant description will be omitted as appropriate. In addition, in order to prevent the illustration from being complicated, only some configurations may be denoted by reference signs, or the illustration may be simplified or enlarged or reduced.

### 1 General Description of Display Apparatuses According to First and Second Aspects of Present Disclosure

A display apparatus according to a first aspect of the present disclosure includes: a plurality of first pixels capable of emitting light of a first color; and a plurality of second pixels capable of emitting light of a second color, in which the plurality of second pixels constitutes a plurality of columns, and the columns of the second pixels include: a plurality of first light emitting elements arranged in a column direction of the columns of the second pixels; a first filter portion provided above the plurality of first light emitting elements and having a second color; and a plurality of second filter portions provided above the plurality of first light emitting elements and at each boundary portion between the second pixels adjacent in the column direction and having a color different from the second color.

In the display apparatus according to the first aspect of the present disclosure, since the second filter portion having a color different from the second color is provided at each boundary portion between the second pixels adjacent in the column direction, at least a part of the light emitted from the first light emitting element toward the boundary portion can be absorbed by the second filter portion. As a result, the viewing angle of the second pixel in the column direction can be narrowed, and a difference in the viewing angle characteristic between the first pixel and the second pixel can be suppressed. Therefore, it is possible to suppress the occurrence of a difference in hue between the image viewed from the front direction and the image obliquely viewed from the column direction. Therefore, the viewing angle characteristic in the column direction can be improved.

A display apparatus according to a second aspect of the present disclosure includes: a plurality of first pixels capable of emitting light of a first color; and a plurality of second pixels capable of emitting light of a second color, in which the plurality of second pixels constitutes a plurality of columns, the columns of the second pixels include: a plurality of first light emitting elements arranged in a column direction of the columns of the second pixels; a color conversion section provided above the plurality of first light emitting elements and capable of converting light emitted from the plurality of first light emitting elements into light of a second color; and a plurality of filter portions provided above the plurality of first light emitting elements and at each boundary portion between the second pixels adjacent in the column direction, the plurality of filter portions having a color different from a color of the second color.

In the display apparatus according to the second aspect of the present disclosure, the filter portion having a color different from the second color is provided at each boundary portion between the second pixels adjacent in the column direction. As a result, at least a part of the light emitted from the light emitting element toward the boundary portion can be absorbed by the filter portion. As a result, the viewing angle of the second pixel in the column direction can be narrowed, and a difference in the viewing angle characteristic between the first pixel and the second pixel can be suppressed. Therefore, it is possible to suppress the occurrence of a difference in hue between the image viewed from the front direction and the image obliquely viewed from the column direction. Therefore, the viewing angle characteristic in the column direction can be improved.

In the display apparatuses according to the first and second aspects of the present disclosure, the column direction of the column of the second pixels may be any direction in the plane of the display surface of the display apparatus, and may be, for example, a vertical direction or a horizontal direction of the display surface of the display apparatus. The column direction of the column of the second pixels represents a direction in which the column of the second pixels extends.

In the display apparatus according to the first aspect of the present disclosure, the second filter portion may be provided on the first filter portion or may be provided in the first filter portion. In a case where the second filter portion is provided in the first filter portion, the thickness of the second filter portion may be substantially the same as the thickness of the first filter portion. In a case where the second filter portion is provided in the first filter portion, the first filter portion may have a surface opposite to the side of the first light emitting element, and a part of the second filter portion may protrude on the surface of the first filter portion. In a case where the second filter portion is provided in the first filter portion, the first filter portion may cover the second filter portion.

In the display apparatus according to the second aspect of the present disclosure, the filter portion may be provided on the wavelength selection section or may be provided in the wavelength selection section. In a case where the filter portion is provided in the wavelength selection section, the thickness of the filter portion may be substantially the same as the thickness of the wavelength selection section. In a case where the filter portion is provided in the wavelength selection section, the wavelength selection section may have a surface opposite to the side of the first light emitting element, and a part of the filter portion may protrude on the surface of the wavelength selection section. In a case where the filter portion is provided in the wavelength selection section, the wavelength selection section may cover the filter portion.

In the display apparatus according to the first and second aspects of the present disclosure, the column of the second pixels may further include a plurality of lenses provided above the plurality of first light emitting elements. At least a part of the plurality of lenses may be shifted in an in-plane direction of the display apparatus with reference to the first light emitting element. The in-plane direction in which the plurality of lenses is shifted is arbitrary, and can be selected according to desired characteristics.

In the display apparatus according to the first aspect of the present disclosure, at least a part of the plurality of second filter portions may be shifted in an in-plane direction of the display apparatus with reference to the first light emitting element. The in-plane direction in which the second filter portion is shifted is arbitrary, and can be selected according to desired characteristics.

In the display apparatus according to the second aspect of the present disclosure, at least a part of the plurality of filter portions may be shifted in an in-plane direction of the display apparatus with reference to the first light emitting element. The in-plane direction in which the filter portion is shifted is arbitrary, and can be selected according to desired characteristics.

In the display apparatus according to the first aspect of the present disclosure, the size of the second pixel in the column direction may be larger than the size of the first pixel in the column direction. Since the second filter portion having a color different from the second color is provided at each boundary portion between the second pixels adjacent in the column direction, it is possible to suppress deterioration of the viewing angle characteristic due to the difference in size between the first pixel and the second pixel.

In the display apparatus according to the second aspect of the present disclosure, the size of the second pixel in the column direction may be larger than the size of the first pixel in the column direction. Since the filter portion having a color different from the second color is provided at each boundary portion between the second pixels adjacent in the column direction, it is possible to suppress deterioration of the viewing angle characteristic due to the difference in size between the first pixel and the second pixel.

In the display apparatus according to the first aspect of the present disclosure, the first color may be red, and the first pixel may have a resonator structure capable of resonating and emphasizing red light. Since the second filter portion having a color different from the second color is provided at each boundary portion between the second pixels adjacent in the column direction, it is possible to suppress deterioration of the viewing angle characteristic due to the resonator structure.

In the display apparatus according to the second aspect of the present disclosure, the first color may be red, and the first pixel may have a resonator structure capable of resonating and emphasizing red light. Since the filter portion having a color different from the second color is provided at each boundary portion between the second pixels adjacent in the column direction, it is possible to suppress deterioration of the viewing angle characteristic due to the resonator structure.

The display apparatus according to the first aspect of the present disclosure may further include a plurality of third pixels capable of emitting light of a third color. In a case where the plurality of third pixels is provided, the second filter portion may have the first color or the third color. In this case, since the second filter portion can be formed using a filter material similar to that of the first pixel or the third pixel, the types of materials for forming the display apparatus can be reduced.

The display apparatus according to the second aspect of the present disclosure may further include a plurality of third pixels capable of emitting light of a third color. In a case where the plurality of third pixels is provided, the filter portion may have the first color or the third color. In this case, since the filter portion can be formed using a filter material similar to that of the first pixel or the third pixel, it is possible to reduce the types of materials for forming the display apparatus.

In the display apparatuses according to the first and second aspects of the present disclosure, the first, second, and third colors may be different from each other, and each of the first, second, and third colors may be one color selected from the group consisting of red, blue, and green. In this case, from the viewpoint of improving the viewing angle characteristic in the column direction, it is preferable that tristimulus values X, Y, and Z of the CIE1931 color system obtained by measuring the white image displayed on the display apparatus from the column direction are substantially equal.

In the display apparatus according to the first and second aspects of the present disclosure, in a case where a plurality of third pixels capable of emitting light of a third color is provided, the plurality of third pixels may constitute a plurality of columns, and the column of the third pixels may include a plurality of second light emitting elements arranged in the column direction and a third filter portion provided above the plurality of second light emitting elements and having the third color. In this case, from the viewpoint of improving the viewing angle characteristic in the column direction, the plurality of third pixels is provided above the plurality of second light emitting elements and at each boundary portion between the third pixels adjacent in the column direction, and preferably further includes a plurality of fourth filter portions having a color different from the third color.

In the display apparatus according to the first and second aspects of the present disclosure, in a case where a plurality of third pixels capable of emitting light of a third color is provided, the first pixel, the second pixel, and the third pixel may be arranged in a stripe array or a square array. In a case where the first pixel, the second pixel, and the third pixel are arranged in a square array, the second pixel may be arranged adjacent to the first pixel and the third pixel.

In the display apparatus according to the first and second aspects of the present disclosure, the column of the second pixels may further include a fifth filter portion provided in the second pixel in plan view and having a color different from the second color. In this case, the viewing angle of the second pixel can be further narrowed.

In the display apparatuses according to the first and second aspects of the present disclosure, the column of the third pixels may further include a sixth filter portion provided in the third pixel in plan view and having a color different from the third color. In this case, the viewing angle of the third pixel can be further narrowed.

In the display apparatuses according to the first and second aspects of the present disclosure, the plurality of first light emitting elements may be configured to emit white light or light of a second color.

In the display apparatus according to the second aspect of the present disclosure, the color conversion section may be a filter portion or a wavelength conversion section. The wavelength conversion section may be a quantum dot section.

The display apparatus according to the first and second aspects of the present disclosure may be provided in an electronic device. For example, the display apparatus may be provided in an eyewear device such as a virtual reality (VR) apparatus, a mixed reality (MR) apparatus, or an augmented reality (AR) apparatus, or may be provided in an electronic view finder (EVF), a small projector, or the like.

In the display apparatuses according to the first and second aspects of the present disclosure, “the target object B is above the target object A” indicates a relative positional relationship between the target object A and the target object B, and is a concept including not only a state in which the target object B is directly positioned on the target object A without sandwiching another target object but also a state in which the target object B is positioned on the target object A with at least one other target object sandwiched therebetween.

In the display apparatuses according to the first and second aspects of the present disclosure, “on the target object A” in an expression such as “the target object B is provided on the target object A” indicates a relative positional relationship between the target object A and the target object B, and is a concept including not only a state in which the target object B is directly located on the target object A without sandwiching another target object but also a state in which the target object B is located on the target object A with at least one other target object interposed therebetween.

### 2 First Embodiment

### Background Leading to Creation of Display Apparatus 101 According to First Embodiment

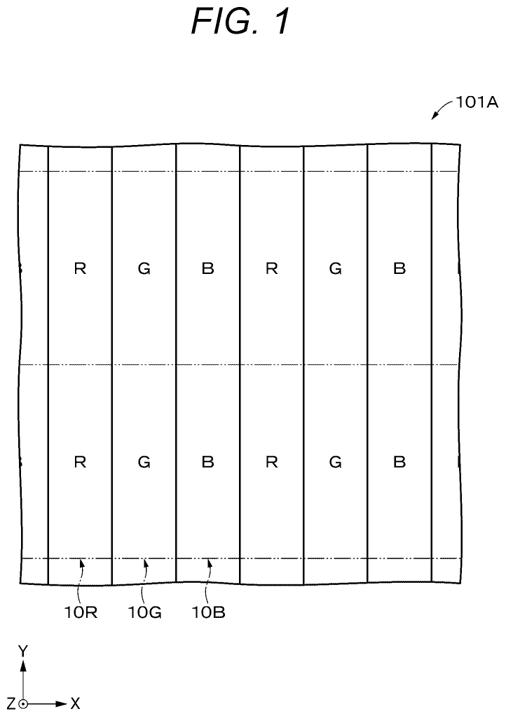

As illustrated in FIG. 1, in a case where the subpixels 10R, 10G, and 10B are arranged in a stripe array, the subpixels 10R and 10R, the subpixels 10G and 10G, and the subpixels 10B and 10B having the same emission color may be arranged adjacent to each other in the Y-axis direction. In the display apparatus 101A in which the subpixels 10R, 10G, and 10B are arranged in this manner, the tristimulus values X, Y, and Z obliquely measured from the Y-axis direction are different, and thus the viewing angle characteristic may be deteriorated. Specifically, in a case where a white image is displayed on the display apparatus 101A, a difference in hue may occur between an image viewed from the Z-axis direction (front direction) and an image viewed obliquely from the Y-axis direction. Note that the tristimulus values X, Y, and Z generally correspond to the emission colors of the three primary colors R, G, and B, that is, the subpixels 10R, 10G, and 10B.

Patent Document 1 describes that, in a case where subpixels are arranged in a square array, viewing angle characteristics are deteriorated due to a difference in aperture ratio of the subpixels. However, as described above, even in a case where the subpixels are arranged in a stripe array and there is no difference in aperture ratio among the subpixels 10R, 10G, and 10B, the viewing angle characteristics may be deteriorated. For example, in a display apparatus in which the subpixels 10R, 10G, and 10B have a resonator structure (cavity structure), not only red light (for example, light having a wavelength of about 600 nm) but also blue light (for example, light having a wavelength of about 400 nm) is easily extracted in the resonator structure of the subpixel 10R. The light obliquely emitted from the OLED layer rather than from the front is likely to have a deviation in the interference distance, and the hue of red tends to be worse. For this reason, the viewing angle characteristic of the subpixel 10R in the Y-axis direction is easily deteriorated as compared with the viewing angle characteristics of the subpixels 10G and 10B in the Y-axis direction.

In the first embodiment, a display apparatus 101 capable of suppressing a difference between the viewing angle characteristic of the subpixel 10R in the Y-axis direction and the viewing angle characteristic of the subpixels 10G and 10B in the Y-axis direction even in a case where the subpixels 10R, 10G, and 10B have a resonator structure will be described.

Note that differences in the viewing angle characteristics of the subpixels 10R, 10G, and 10B in the Y-axis direction, that is, differences in the tristimulus values X, Y, and Z of the subpixels 10R, 10G, and 10B in the Y-axis direction may also occur due to factors other than the resonator structure. For example, a difference in the viewing angle characteristics of the subpixels 10R, 10G, and 10B in the Y-axis direction may occur due to a difference in characteristics due to the film thickness of the organic EL included in the subpixels 10R, 10G, and 10B, a difference in density and film thickness of the color filters included in the subpixels 10R, 10G, and 10B, and the like. Therefore, the present disclosure is not limited to the display apparatus 101 having a resonator structure.

### Schematic Configuration of Display Apparatus 101

FIG. 1 is a plan view of a display apparatus 101 according to a first embodiment. The display apparatus 101 may be a top emission type OLED display apparatus. As illustrated in FIG. 1, the display apparatus 101 includes an effective pixel region RE1 and a peripheral region RE2 provided around the effective pixel region RE1. In the present specification, a first direction and a second direction orthogonal to each other in the display surface of the display apparatus 101 are referred to as an X-axis direction and a Y-axis direction, respectively, and a direction perpendicular to the display surface of the display apparatus 101 is referred to as a Z-axis direction. In the first embodiment, an example in which the X-axis direction is the horizontal direction in the display surface and the Y-axis direction is the vertical direction in the display surface will be described.

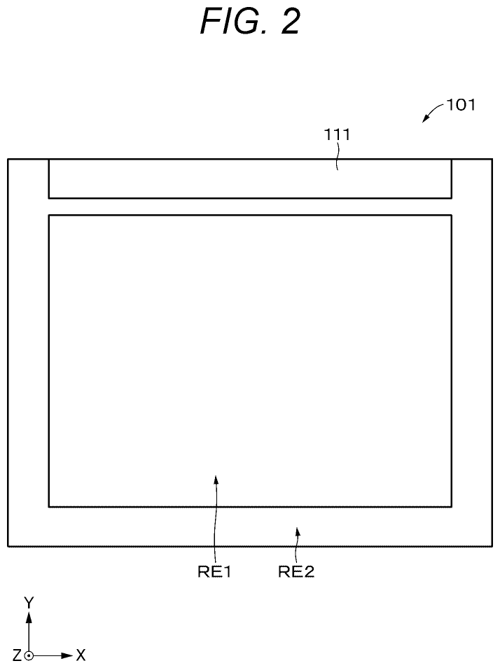

FIG. 2 is an enlarged plan view illustrating a part of the effective pixel region RE1. The plurality of subpixels 10R, 10G, and 10B is two-dimensionally arranged in a specified array in the effective pixel region RE1. In the first embodiment, an example in which the specified array is a stripe array will be described. A pad portion 111, a video display driver (not illustrated), and the like are provided in the peripheral region RE2. A flexible printed circuit (FPC) (not illustrated) may be connected to the pad portion 111.

The subpixel 10R can emit red light (light of the first color). The subpixel 10G can emit green light (light of the second color). The subpixel 10B can emit blue light (light of the third color). In the following description, in a case where the subpixels 10R, 10G, and 10B are collectively referred to without being particularly distinguished, the subpixels 10R, 10G, and 10B may be referred to as the subpixels 10. One pixel includes, for example, a plurality of adjacent subpixels 10R, 10G, and 10B. However, the configuration of one pixel is not limited to this example. The subpixel 10R may have a rectangular shape in plan view. In the first embodiment, one of the subpixel 10G and the subpixel 10B is an example of a second pixel in the first aspect of the present disclosure and the second aspect of the present disclosure, and the other is an example of a third pixel in the first aspect of the present disclosure and the second aspect of the present disclosure. The subpixel 10R is an example of a first pixel in the first aspect of the present disclosure and the second aspect of the present disclosure.

The plurality of subpixels 10R constitutes a column of the plurality of subpixels 10R. The column of the subpixel 10R is configured by arranging a plurality of subpixels 10R in the Y-axis direction. The plurality of subpixels 10G constitutes a column of the plurality of subpixels 10G. The column of the subpixel 10G is configured by arranging a plurality of subpixels 10G in the Y-axis direction. The plurality of subpixels 10B constitutes a column of the plurality of subpixels 10B. The column of the subpixels 10B is configured by arranging a plurality of subpixels 10B in the Y-axis direction.

From the viewpoint of improving the viewing angle characteristic in the Y-axis direction (column direction), tristimulus values X, Y, and Z of the CIE1931 color system obtained by measuring the white image displayed on the display apparatus 101 from the Y-axis direction (column direction) are preferably substantially equal within the range of the viewing angle ±50°, and more preferably substantially equal within the range of the viewing angle ±70°.

### Layer Configuration of Display Apparatus 101

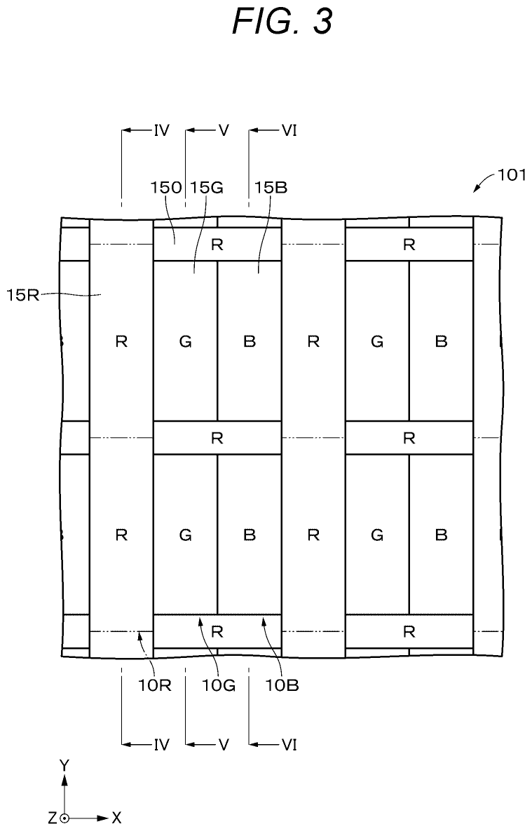

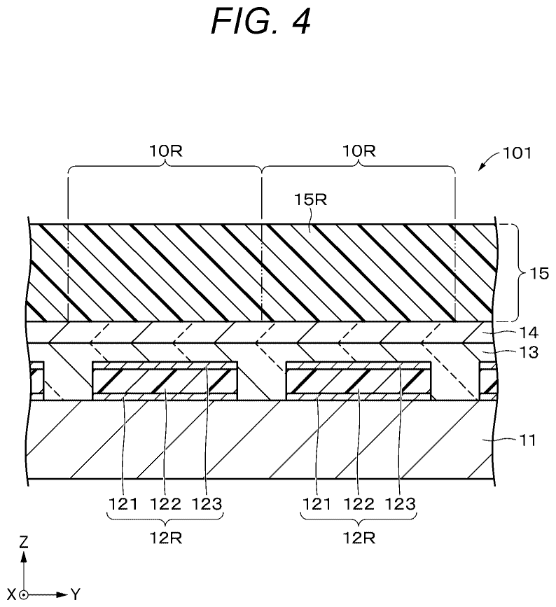

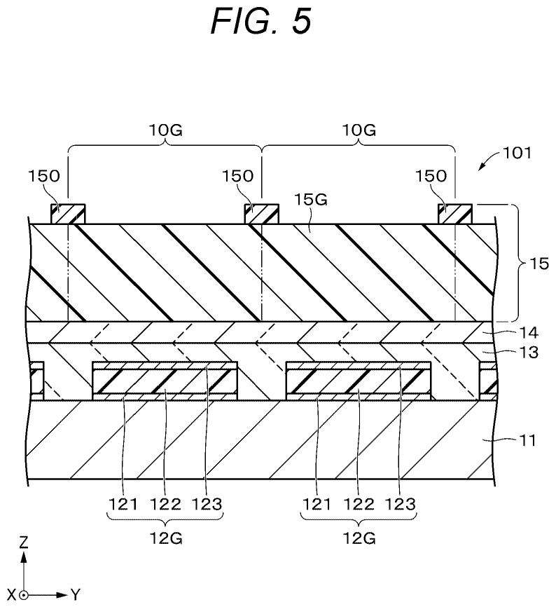

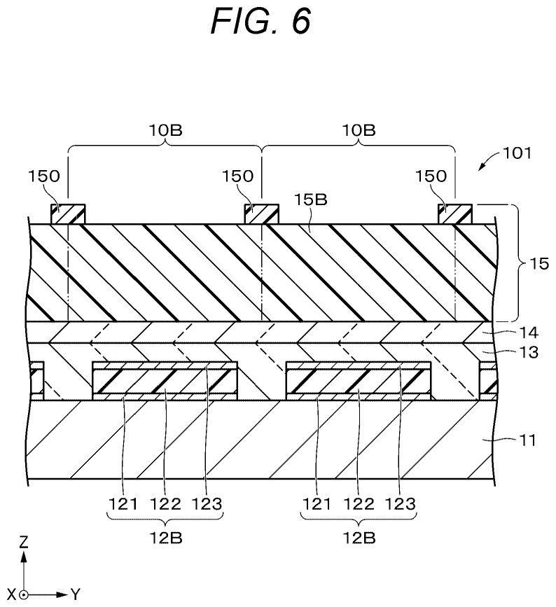

FIG. 4 is a cross-sectional view taken along line IV-IV of FIG. 3. FIG. 5 is a cross-sectional view taken along line V-V of FIG. 3. FIG. 6 is a cross-sectional view taken along line VI-VI of FIG. 3. The display apparatus 101 includes a drive substrate 11, a plurality of light emitting elements 12R, a plurality of light emitting elements 12G, a plurality of light emitting elements 12B, a protective layer 13, a planarization layer 14, and a color filter 15. In the following description, in a case where the light emitting elements 12R, 12G, and 12B are collectively referred to without being particularly distinguished, the light emitting elements 12R, 12G, and 12B may be referred to as light emitting elements 12.

In the present specification, of both surfaces of each layer constituting the display apparatus 101, a surface on the display surface side (top side) of the display apparatus 101 may be referred to as a first surface, and a surface on the opposite side (bottom side) to the display surface of the display apparatus 101 may be referred to as a second surface. In the present specification, a plan view means a plan view when a target object is viewed from a direction perpendicular to the first surface.

### Drive Substrate 11

The drive substrate 11 is a so-called backplane, and can drive the plurality of light emitting elements 12. The drive substrate 11 includes, for example, a substrate and an insulating layer in order. A plurality of drive circuits (not illustrated), a plurality of wirings (not illustrated), and the like may be provided on the first surface side of the substrate.

The substrate may be, for example, a semiconductor substrate on which a transistor or the like is easily formed, or a glass substrate or a resin substrate having low moisture and oxygen permeability. The semiconductor substrate includes, for example, amorphous silicon, polycrystalline silicon, monocrystalline silicon, or the like. The glass substrate includes, for example, high strain point glass, soda glass, borosilicate glass, forsterite, lead glass, quartz glass, or the like. The resin substrate contains, for example, at least one selected from the group consisting of polymethyl methacrylate, polyvinyl alcohol, polyvinyl phenol, polyether sulfone, polyimide, polycarbonate, polyethylene terephthalate, polyethylene naphthalate, and the like.

The insulating layer is provided on the first surface of the substrate and covers the plurality of drive circuits, the plurality of wirings, and the like. The insulating layer includes a plurality of contact portions (not illustrated) therein. The plurality of contact portions electrically connects the light emitting element 12 and the wiring or the drive circuit. The contact portion contains, for example, at least one metal selected from the group consisting of copper (Cu), titanium (Ti), and the like.

The insulating layer may be an organic insulating layer, an inorganic insulating layer, or a laminate thereof. The organic insulating layer contains, for example, at least one selected from the group consisting of a polyimide resin, an acrylic resin, a novolac resin, and the like. The inorganic insulating layer contains, for example, at least one selected from the group consisting of silicon oxide (SiOₓ), silicon nitride (SiNₓ), silicon oxynitride (SiOₓN_{y}), and the like.

### Light Emitting Elements 12R, 12G, and 12B

The light emitting element 12 may be an organic light emitting diode element (OLED element). The light emitting element 12 has a first electrode 121, an OLED layer 122, and a second electrode 123 in order on the first surface of the drive substrate 11. The light emitting element 12R is included in the subpixel 10R. The light emitting element 12G is included in the subpixel 10G. The light emitting element 12B is included in the subpixel 10B.

The light emitting element 12R can emit red light under the control of a drive circuit or the like. More specifically, the light emitting element 12R has a resonator structure, and can resonate and emphasize and emit a component of red light contained in white light emitted by the OLED layer 122 by the resonator structure.

The light emitting element 12G can emit green light under the control of a drive circuit or the like. More specifically, the light emitting element 12G has a resonator structure, and can resonate and emphasize and emit a component of green light included in white light emitted by the OLED layer 122 by the resonator structure.

The light emitting element 12B can emit blue light under the control of a drive circuit or the like. More specifically, the light emitting element 12B has a resonator structure, and can resonate and emphasize and emit a component of blue light included in white light emitted by the OLED layer 122 by the resonator structure. Details of the resonator structure will be described in <7 Example of Resonator Structure>.

The plurality of light emitting elements 12 is two-dimensionally arranged on the first surface of the drive substrate 11 in a specified array. The specified array is as described as the specified array of the plurality of subpixels 10. The plurality of light emitting elements 12R constitutes a row of the plurality of light emitting elements 12R. The row is configured by a plurality of light emitting elements 12R arranged in the Y-axis direction. The plurality of light emitting elements 12G constitutes a row of the plurality of light emitting elements 12G. The row is formed by arranging the plurality of light emitting elements 12G in the Y-axis direction. The plurality of light emitting elements 12B constitutes a row of the plurality of light emitting elements 12B. The row is formed by arranging the plurality of light emitting elements 12B in the Y-axis direction.

### First Electrode 121

The first electrode 121 is provided on the second surface side of the OLED layer 122. The first electrode 121 is an individual electrode individually provided in the plurality of light emitting elements 12 in the effective pixel region RE1. That is, the first electrode 121 is divided between the light emitting elements 12 adjacent in the in-plane direction of the first surface of the drive substrate 11 in the effective pixel region RE1. In the first embodiment, the first electrode 121 is an anode. When a voltage is applied between the first electrode 121 and the second electrode 123, holes are injected from the first electrode 121 into the OLED layer 122.

The first electrode 121 may include, for example, a metal layer, or may include a metal layer and a transparent conductive oxide layer. In a case where the first electrode 121 is constituted by a metal layer and a transparent conductive oxide layer, the transparent conductive oxide layer is preferably provided on the OLED layer 122 side from the viewpoint of adjoining a layer having a high work function to the OLED layer 122.

The metal layer may have a function as a reflection layer that reflects light emitted from the OLED layer 122. The metal layer contains, for example, at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain at least one metal element described above as a constituent element of the alloy. Specific examples of the alloy include an aluminum alloy and a silver alloy. Specific examples of the aluminum alloy include AlNd and AlCu.

A base layer (not illustrated) may be provided adjacent to the second surface side of the metal layer. The base layer may be capable of improving the crystal orientation of the metal layer at the time of forming the metal layer. The base layer contains, for example, at least one metal element selected from the group consisting of titanium (Ti) and tantalum (Ta). The base layer may contain at least one metal element described above as a constituent element of the alloy.

The transparent conductive oxide layer contains a transparent conductive oxide. The transparent conductive oxide contains, for example, at least one selected from the group consisting of a transparent conductive oxide containing indium (hereinafter, referred to as an “indium-based transparent conductive oxide”), a transparent conductive oxide containing tin (hereinafter, referred to as a “tin-based transparent conductive oxide”), and a transparent conductive oxide containing zinc (hereinafter, referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO), or fluorine-doped indium oxide (IFO). Among these transparent conductive oxides, indium tin oxide (ITO) is particularly preferable. This is because indium tin oxide (ITO) has a particularly low hole injection barrier into the OLED layer 122 as a work function, and thus the drive voltage of the display apparatus 101 can be particularly reduced. The tin-based transparent conductive oxide contains, for example, tin oxide, antimony-doped tin oxide (ATO), or fluorine-doped tin oxide (FTO). The zinc-based transparent conductive oxide contains, for example, zinc oxide, aluminum-doped zinc oxide (AZO), boron-doped zinc oxide, or gallium-doped zinc oxide (GZO).

### OLED Layer 122

The OLED layer 122 can emit white light. The OLED layer 122 is provided between the first electrode 121 and the second electrode 123. The OLED layer 122 is individually provided by the plurality of light emitting elements 12 in the effective pixel region RE1. That is, the OLED layer 122 is divided between the light emitting elements 12 adjacent in the in-plane direction of the first surface of the drive substrate 11 in the effective pixel region RE1.

The OLED layer 122 may be constituted by a laminate including an organic light emitting layer, and in this case, some layers (for example, electron injection layers) of the laminate may be inorganic layers. The OLED layer 122 may be an OLED layer including a single-layer light emitting unit, an OLED layer (tandem structure) including a two-layer light emitting unit, or an OLED layer having a structure other than these. The OLED layer including the single-layer light emitting unit has a configuration in which, for example, a hole injection layer, a hole transport layer, a red light emitting layer, a light emission separation layer, a blue light emitting layer, a green light emitting layer, an electron transport layer, and an electron injection layer are laminated in this order from the first electrode 121 toward the second electrode 123. The OLED layer including two light emitting units has a configuration in which, for example, a hole injection layer, a hole transport layer, a blue light emitting layer, an electron transport layer, a charge generation layer, a hole transport layer, a yellow light emitting layer, an electron transport layer, and an electron injection layer are laminated in this order from the first electrode 121 toward the second electrode 123.

The hole injection layer can enhance hole injection efficiency into each light emitting layer and suppress leakage. The hole transport layer can enhance hole transport efficiency to each light emitting layer. The electron injection layer can enhance electron injection efficiency into each light emitting layer. The electron transport layer can enhance electron transport efficiency to each light emitting layer. The light emission separation layer is a layer for adjusting injection of carriers into each light emitting layer, and light emission balance of each color is adjusted by injecting electrons or holes into each light emitting layer via the light emission separation layer. The charge generation layer can supply electrons and holes to two light emitting layers provided so as to sandwich the charge generation layer.

When an electric field is applied to each of the red light emitting layer, the green light emitting layer, the blue light emitting layer, and the yellow light emitting layer, recombination occurs between holes injected from the first electrode 121 or the charge generation layer and electrons injected from the second electrode 123 or the charge generation layer, and red light, green light, blue light, and yellow light can be emitted.

### Second Electrode 123

The second electrode 123 is provided on the first surface side of the OLED layer 122. The second electrode 123 is an individual electrode individually provided in the plurality of light emitting elements 12 in the effective pixel region RE1. That is, the second electrode 123 is divided between the light emitting elements 12 adjacent in the in-plane direction of the first surface of the drive substrate 11 in the effective pixel region RE1.

In the first embodiment, the second electrode 123 is a cathode. When a voltage is applied between the first electrode 121 and the second electrode 123, electrons are injected from the second electrode 123 into the OLED layer 122. The second electrode 123 has light-transmitting properties with respect to visible light, and is configured to be able to extract light resonated by the resonator structure. In the present specification, visible light refers to light in a wavelength range of 360 nm to 830 nm.

The second electrode 123 is preferably constituted by a material having high light-transmitting properties and a small work function in order to enhance light emission efficiency. The second electrode 123 includes, for example, at least one of a metal layer or a transparent conductive oxide layer. More specifically, the second electrode 123 includes a single-layer film of a metal layer or a transparent conductive oxide layer, or a laminated film of a metal layer and a transparent conductive oxide layer. In order to enhance the resonance effect of light due to the resonator structure, the second electrode 123 preferably includes a metal layer. In a case where the second electrode 123 is constituted by a laminated film, the metal layer may be provided on the OLED layer 122 side, or the transparent conductive oxide layer may be provided on the OLED layer 122 side, but from the viewpoint of adjoining a layer having a low work function to the OLED layer 122, the metal layer is preferably provided on the OLED layer 122 side.

The metal layer contains, for example, at least one metal element selected from the group consisting of magnesium (Mg), aluminum (Al), silver (Ag), calcium (Ca), and sodium (Na). The metal layer may contain at least one metal element described above as a constituent element of the alloy. Specific examples of the alloy include an MgAg alloy, an MgAl alloy, and an AlLi alloy. The transparent conductive oxide layer contains a transparent conductive oxide. As the transparent conductive oxide, a material similar to the transparent conductive oxide of the first electrode 121 described above can be exemplified.

### Protective Layer 13

The protective layer 13 is provided on the first surface of the drive substrate 11 so as to cover the plurality of light emitting elements 12. The protective layer 13 has light-transmitting properties with respect to light emitted from the light emitting element 12. The protective layer 13 can protect the plurality of light emitting elements 12 and the like. For example, the protective layer 13 can suppress moisture ingress into the plurality of light emitting elements 12 and the like from the external environment. In addition, in a case where the second electrode 123 is constituted by a metal layer, the protective layer 13 may have a function of suppressing oxidation of the metal layer.

The protective layer 13 contains, for example, at least one of an inorganic material or an organic material having low hygroscopicity. The protective layer 13 may have a single-layer structure or a multilayer structure. In a case where the thickness of the protective layer 13 is increased, it is preferable to have a multilayer structure. This is to alleviate the internal stress in the protective layer 13. The inorganic material includes, for example, at least one selected from the group consisting of silicon oxide (SiOₓ), silicon nitride (SiNₓ), silicon oxynitride (SiOₓN_{y}), titanium oxide (TiOₓ), aluminum oxide (AlOₓ), and the like. The organic material includes, for example, a cured product of at least one resin selected from the group consisting of a thermosetting resin, a photosensitive resin, and the like. The photosensitive resin includes, for example, an ultraviolet curable resin. Specifically, the organic material includes, for example, at least one selected from the group consisting of an acrylic resin, a polyimide resin, a novolac resin, an epoxy-based resin, a norbornene-based resin, a parylene-based resin, and the like.

The protective layer 13 preferably includes a deposited layer on which an atomic layer is deposited. The deposited layer may be an atomic layer deposition (ALD) layer. When the protective layer 13 includes a deposited layer, the effect of suppressing moisture ingress by the protective layer 13 can be improved. The deposited layer includes, for example, a metal oxide or a metal nitride. The metal oxide includes, for example, aluminum oxide (AlOₓ) or titanium oxide (TiOₓ). The metal nitride includes, for example, titanium nitride (TiNₓ).

### Planarization Layer 14

The planarization layer 14 is provided on the first surface of the protective layer 13. The planarization layer 14 can fill the irregularities of the first surface of the protective layer 13 and form the flat first surface above the protective layer 13. The planarization layer 14 has light-transmitting properties with respect to light emitted from the light emitting element 12. The planarization layer 14 contains, for example, at least one of an organic material or an inorganic material.

The organic material includes, for example, a cured product of a photosensitive resin. The photosensitive resin may contain either a positive photosensitive resin or a negative photosensitive resin. Specifically, the photosensitive resin contains, for example, at least one selected from the group consisting of polyimide, a polyimide precursor, polybenzoxazole, a polybenzoxazole precursor, an acrylic resin, a phenolic resin, a siloxane resin, and the like. As the inorganic material, a material similar to the inorganic material of the protective layer 13 can be exemplified.

### Color Filter 15

The color filter 15 is a so-called on-chip color filter (OCCF). The color filter 15 is provided above the plurality of light emitting elements 12. More specifically, the color filter 15 is provided on the first surface of the planarization layer 14.

The color filter 15 includes a plurality of filter portions 15R, a plurality of filter portions 15G, a plurality of filter portions 15B, and a plurality of filter portions 150. One of the filter portion 15G and the filter portion 15B is an example of a first filter portion in the first aspect of the present disclosure and an example of a color conversion section in the second aspect of the present disclosure, and the other is an example of a third filter portion in the first aspect of the present disclosure. The filter portion 150 is an example of the second filter portion and the fourth filter portion in the first aspect of the present disclosure, and an example of the filter portion in the second aspect of the present disclosure.

### Filter Portions 15R, 15G, and 15B

The plurality of filter portions 15R, 15G, and 15B are arranged in a stripe array similarly to the plurality of subpixels 10R, 10G, and 10B. The filter portion 15R, the filter portion 15G, and the filter portion 15B have a linear shape extending in the Y-axis direction (direction of column formed by subpixels 10R, 10G, and 10B).

The filter portion 15R is provided above the row of the light emitting elements 12R. The filter portion 15G is provided above the row of the light emitting elements 12G. The filter portion 15B is provided above the row of the light emitting elements 12B. The column of the subpixel 10R includes a column of the light emitting element 12R and a filter portion 15R provided above the column of the light emitting element 12R. The column of the subpixel 10G includes a column of the light emitting element 12G and a filter portion 15G provided above the column of the light emitting element 12G. The column of the subpixel 10B includes a column of the light emitting element 12B and a filter portion 15B provided above the column of the light emitting element 12B.

The filter portion 15R has a red color. The filter portion 15R can absorb visible light components other than red light while transmitting red light components in light emitted from the light emitting element 12R. The filter portion 15G has a green color. The filter portion 15G can absorb visible light components other than green light while transmitting a green light component in light emitted from the light emitting element 12G. The filter portion 15B has blue color. The filter portion 15B can absorb visible light components other than blue light while transmitting blue light components among light emitted from the light emitting element 12B. As described above, the light emitted from each of the light emitting elements 12R, 12G, and 12B passes through the filter portions 15R, 15G, and 15B, so that the color purity of the subpixels 10R, 10G, and 10B can be improved.

The filter portion 15R includes, for example, a red color resist. The filter portion 15G includes, for example, a green color resist. The filter portion 15B includes, for example, a blue color resist.

### Filter Portion 150

The plurality of filter portions 150 is provided on the first surface of the filter portion 15G and the first surface of the filter portion 15G. The filter portion 150 is located at a boundary portion between the subpixels 10G adjacent in the Y-axis direction and a boundary portion between the subpixels 10B adjacent in the Y-axis direction in plan view. The filter portion 150 may be configured to divide between the subpixels 10G adjacent in the Y-axis direction and between the subpixels 10B adjacent in the Y-axis direction in plan view.

The filter portion 150 may have an elongated shape in plan view. In a case where the filter portion 150 has an elongated shape as described above, the longitudinal direction of the elongated shape may substantially coincide with the X-axis direction. The length of the filter portion 151 in the X-axis direction may be substantially equal to the total value of the width of the filter portion 15G in the X-axis direction and the width of the filter portion 15B in the X-axis direction.

The elongated filter portion 150 has, for example, a substantially rectangular shape or an oval shape. In the present embodiment, the substantially rectangular shape is not limited to a rectangle in a strict sense, and includes a shape that is visually recognized as being close to a rectangle. For example, the rectangular shape may be distorted or deformed within a range of tolerance, error, or the like. The substantially rectangular shape includes a shape in which corners of a rectangle are rounded and a shape in which corners of a rectangle are cut away. The oval shape includes shapes such as an oval shape, an elliptical shape, and an egg shape.

The filter portion 150 has a color different from those of the filter portion 15G and the filter portion 15R. Since the filter portion 151 has a color different from those of the filter portion 15G and the filter portion 15R, it is possible to shield light incident on a boundary portion between the light emitting element 12 and the subpixel 10G and a boundary portion between the light emitting element 12 and the subpixel 10B. Therefore, the viewing angles of the subpixel 10G and the subpixel 10B can be narrowed, and a difference in the viewing angle characteristics of the tristimulus values, that is, a difference in the viewing angle characteristics of the subpixels 10G and 10B and the subpixel 10R can be suppressed.

The filter portion 150 preferably has red of the same color as the filter portion 15R. Since the filter portion 150 has red of the same color as that of the filter portion 15R, the combination of the filter portion 150 and the filter portion 15G can shield light in substantially the entire visible light region at the boundary portion between the subpixels 10G, and the combination of the filter portion 150 and the filter portion 15B can shield light in substantially the entire visible light region at the boundary portion between the subpixels 10B. Therefore, the viewing angle characteristic in the Y-axis direction can be further improved. Furthermore, since the filter portion 150 has red of the same color as the filter portion 15R, the filter portion 150 can be formed using the same material as the filter portion 15R. Therefore, the types of materials required for manufacturing the display apparatus 101 can be reduced.

The filter portion 150 includes a color resist of a color different from those of the filter portion 15G and the filter portion 15B. The filter portion 150 preferably includes a red color resist of the same color as the filter portion 15R, and may include the same color resist as the filter portion 15R.

### Method for Manufacturing Display Apparatus 101

Hereinafter, an example of a method for manufacturing the display apparatus 101 according to the first embodiment will be described.

### Step of Forming Light Emitting Element 12

First, the plurality of light emitting elements 12 is formed on the first surface of the drive substrate 11. As a method for forming the light emitting element 12, for example, a known method can be used.

### Step of Forming Protective Layer 13

Next, the protective layer 13 is formed on the first surface of the drive substrate 11 by, for example, a CVD method so as to cover the plurality of light emitting elements 12.

### Step of Forming Planarization Layer 14

Next, for example, a photosensitive resin is applied onto the first surface of the protective layer 13, and then the photosensitive resin is irradiated with light to cure the photosensitive resin. Thus, the planarization layer 14 is formed on the first surface of the protective layer 13.

### Step of Forming Color Filter 15

Next, a green color resist is applied onto the first surface of the planarization layer 14, and after pattern exposure by irradiation with ultraviolet rays through a photomask, development is performed to form the plurality of filter portions 15G. Next, a red color resist is applied onto the first surface of the planarization layer 14 so as to cover the plurality of filter portions 15G, and after pattern exposure by irradiation with ultraviolet rays through a photomask, development is performed to form the plurality of filter portions 15R. Next, a blue color resist is applied onto the first surface of the planarization layer 14 so as to cover the plurality of filter portions 15G and the plurality of filter portions 15R, and after pattern exposure by irradiation with ultraviolet rays through a photomask, development is performed to form the plurality of filter portions 15B.

Next, a color resist having a color different from those of the filter portion 15G and the filter portion 15B is applied onto the first surfaces of the filter portion 15R, the filter portion 15G, and the filter portion 152, and after pattern exposure by irradiation with ultraviolet rays through a photomask, development is performed, so that the plurality of filter portions 150 is formed at the boundary portion between the subpixels 10G and the boundary portion between the subpixels 10B, respectively. As a result, the color filter 15 is formed on the first surface of the planarization layer 14. The resist for forming the filter portion 150 is preferably a red color resist having the same color as the filter portion 15R. In this case, the number of types of color resists required for manufacturing the display apparatus 101 can be reduced.

### Operation and Effect

As described above, in the display apparatus 101 according to the first embodiment, the filter portion 150 is provided at the boundary portion between the subpixels 10G adjacent in the Y-axis direction and the boundary portion between the subpixels 10B adjacent in the Y-axis direction. The filter portion 150 has a color different from that of the subpixel 10G and the subpixel 10B. As a result, the viewing angles of the subpixels 10G and 10B in the Y-axis direction can be narrowed, and a difference in the viewing angle characteristic between the subpixels 10G and 10B and the subpixel 10R can be suppressed. Therefore, it is possible to suppress the occurrence of a difference in hue between the image viewed from the Z-axis direction (front direction) and the image obliquely viewed from the Y-axis direction. Therefore, in the display apparatus 101 in which the subpixels 10R, 10G, and 10B having the resonator structure are arrayed in stripes, the viewing angle characteristic in the Y-axis direction can be improved.

### 3 Second Embodiment

### Background Leading to Creation of Display Apparatus 102 According to Second Embodiment

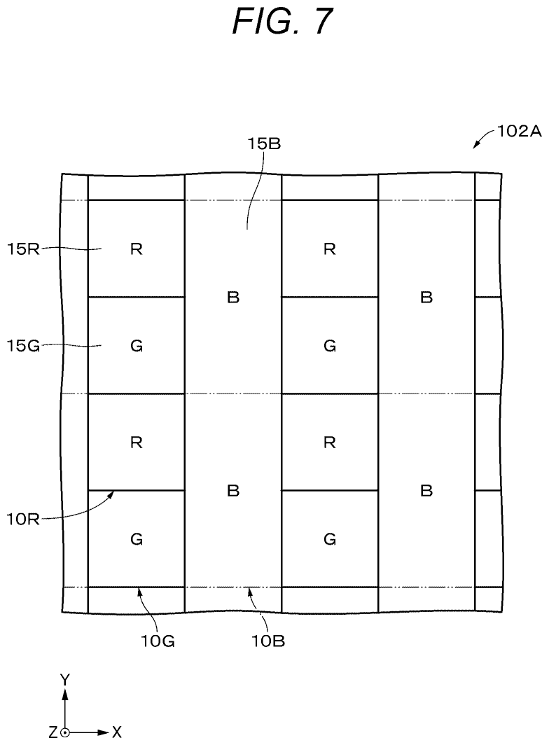

In the display apparatus 102A in which the subpixels 10R, 10G, and 10B are arranged in a square manner, as illustrated in FIG. 7, the subpixels 10R and 10G are alternately arranged in the Y-axis direction, whereas the subpixel 10B may be continuously arranged in the Y-axis direction. In the display apparatus 102A having such a pixel array, tristimulus values X, Y, and Z obliquely measured from the Y-axis direction are different, and viewing angle characteristics deteriorate.

In the second embodiment, a display apparatus 102 capable of improving the viewing angle characteristic in the Y-axis direction even in a case where the subpixels 10R, 10G, and 10B are arranged in a square manner will be described.

### Configuration of Display Apparatus 102

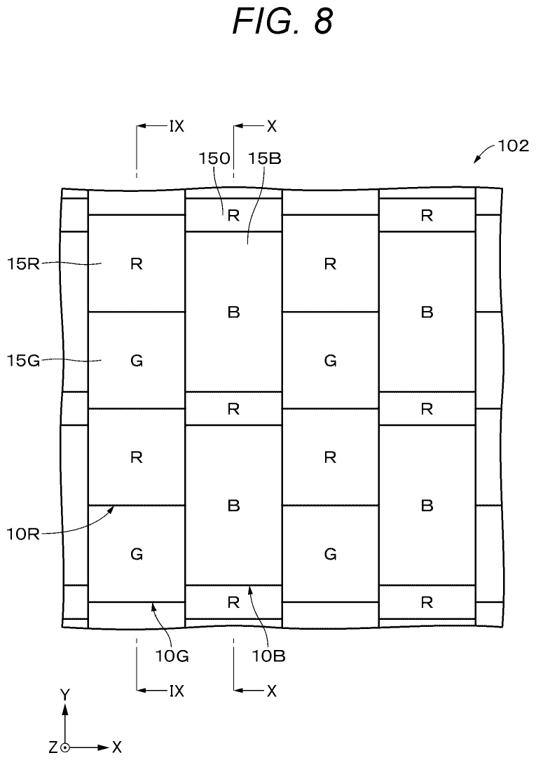

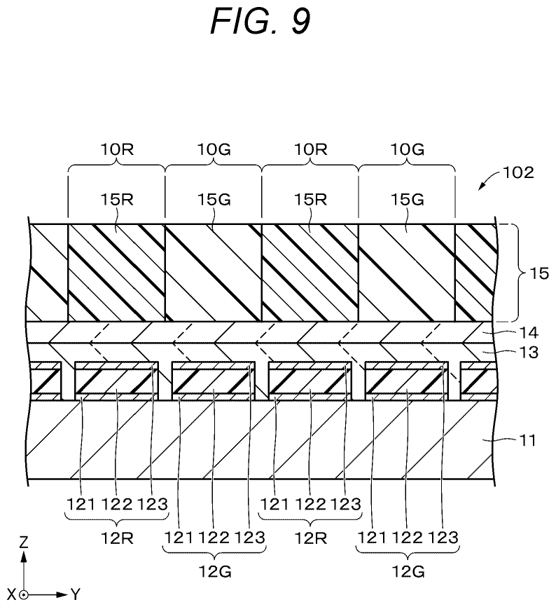

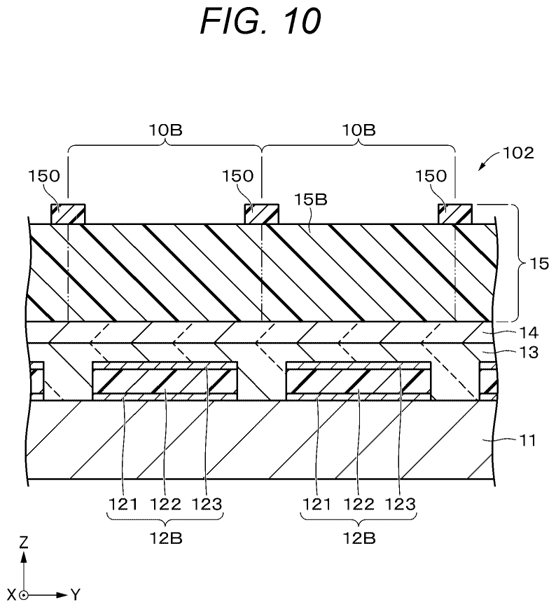

FIG. 8 is an enlarged plan view illustrating a part of an effective pixel region REI of the display apparatus 102 according to the second embodiment. FIG. 9 is a cross-sectional view taken along line IX-IX of FIG. 9. FIG. 10 is a cross-sectional view taken along line X-X of FIG. 10. The display apparatus 102 is different from the display apparatus 101 according to the first embodiment in that the subpixels 10R, 10G, and 10B are arranged in a square manner, and the filter portion 150 is provided at a boundary portion between the subpixels 10B adjacent in the Y-axis direction.

In the plurality of subpixels 10R and the plurality of subpixels 10G, the subpixels 10R and the subpixels 10G are alternately arranged in the Y-axis direction, and form a plurality of columns extending in the Y-axis direction. The subpixels 10R and 10G have a square shape in plan view.

The plurality of subpixels 10B is continuously arranged in the Y-axis direction and constitutes a plurality of columns extending in the Y-axis direction. The subpixel 10B has a rectangular shape in plan view. One subpixel 10B is arranged adjacent to a set of subpixels 10R and 10G. The size of the subpixel 10B in the Y-axis direction (the column direction of the column of the subpixel 10B) is larger than the sizes of the subpixels 10R and 10G in the Y-axis direction.

In the second embodiment, the display apparatus 102 may include a plurality of light emitting elements 12R, 12G, and 12B having a resonator structure, or may include a light emitting element 12 that does not have a resonator structure and can emit white light instead of these light emitting elements 12R, 12G, and 12B.

### Operation and Effect

As described above, in the display apparatus 102 according to the second embodiment, the filter portion 150 is provided at the boundary portion between the subpixels 10B adjacent in the Y-axis direction. The filter portion 150 has a color different from that of the subpixel 10B. As a result, the viewing angle of the subpixel 10B in the Y-axis direction can be narrowed, and a difference in the viewing angle characteristic between the subpixels 10R and 10G and the subpixel 10B can be suppressed. Therefore, it is possible to suppress the occurrence of a difference in hue between the image viewed from the Z-axis direction (front direction) and the image obliquely viewed from the Y-axis direction. Therefore, in the display apparatus 102 in which the subpixels 10R, 10G, and 10B are arranged in a square manner, the viewing angle characteristic in the Y-axis direction can be improved.

### 4 Modifications

### Modification 1

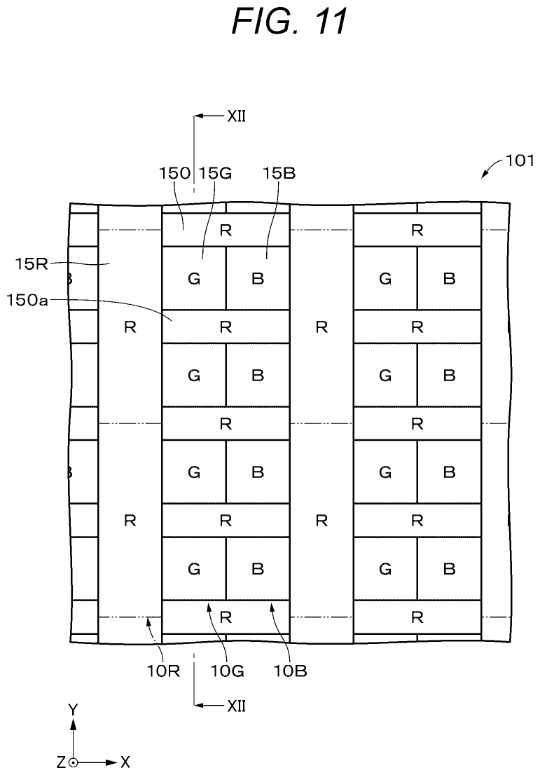

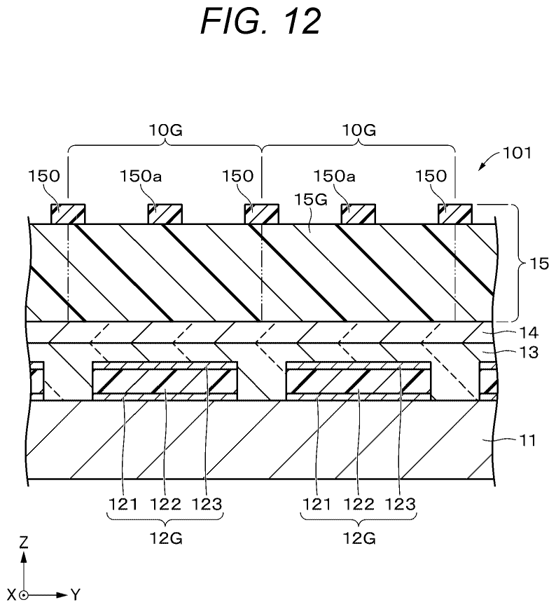

As illustrated in FIGS. 11 and 12, the display apparatus 101 according to the first embodiment may further include a filter portion 150a. The filter portion 150a is disposed in the subpixels 10G and 10B, that is, between the filter portions 150 adjacent to each other in the Y-axis direction. The filter portion 150a may be located at the center of the subpixels 10G and 10B in the Y-axis direction. The filter portion 150a may be similar to the filter portion 150 in points other than the arrangement position. The filter portion 150a is an example of a fifth filter portion in the first aspect of the present disclosure and the second aspect of the present disclosure.

Since the display apparatus 101 further includes the filter portion 150a, the viewing angles of the subpixels 10G and 10B in the Y-axis direction can be further narrowed.

The configuration of the filter portion 150a is not limited to the above example, and for example, the filter portion 150a may be provided only in the subpixel 10G or the subpixel 10B. In this case, the viewing angle of the subpixel 10G in the Y-axis direction or the viewing angle of the subpixel 10B in the Y-axis direction can be further narrowed.

### Modification 2

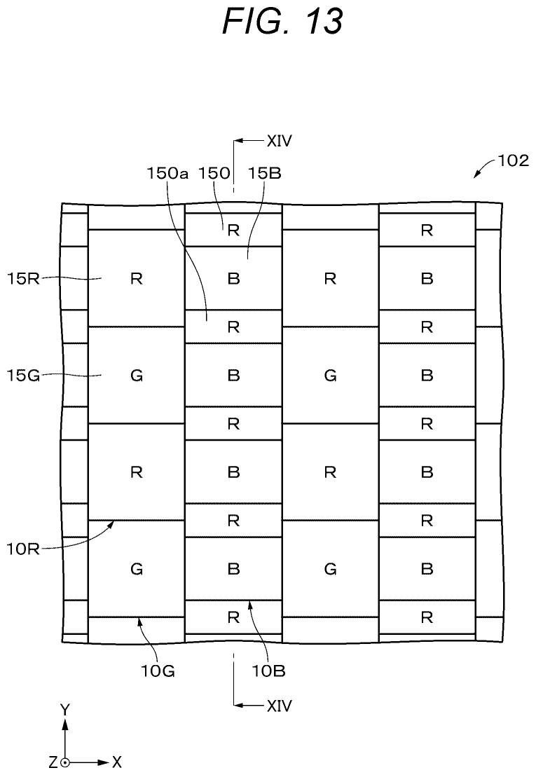

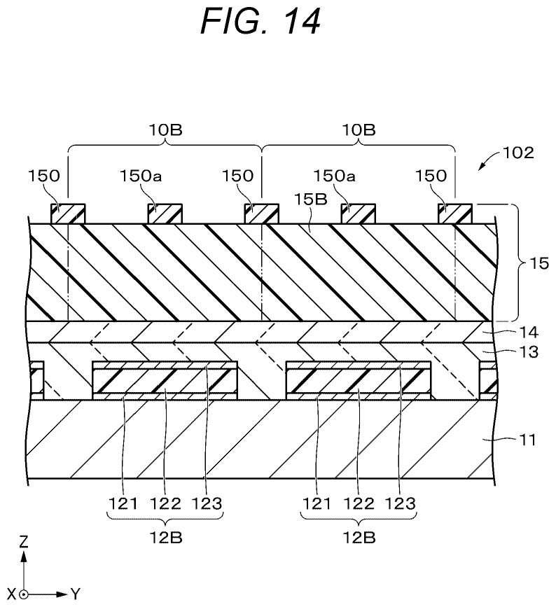

As illustrated in FIGS. 13 and 14, the display apparatus 102 according to the second embodiment may further include a filter portion 150a. The filter portion 150a is disposed in the subpixel 10B, that is, between the filter portions 150 adjacent in the Y-axis direction. The filter portion 150a may be located at the center of the subpixel 10B in the Y-axis direction.

Since the display apparatus 101 further includes the filter portion 150a, the viewing angle of the subpixel 10B in the Y-axis direction can be further narrowed.

### Modification 3

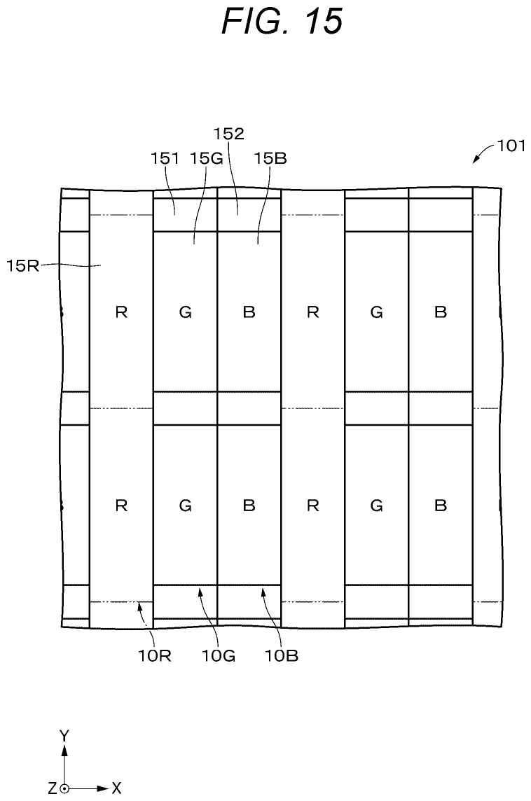

In the first embodiment, an example in which the color filter 15 includes the plurality of filter portions 150 has been described (see FIG. 3). However, the configuration of the color filter 15 is not limited to this example. For example, the color filter 15 may include a plurality of filter portions 151 and a plurality of filter portions 152 as illustrated in FIG. 15 instead of the plurality of filter portions 150.

The plurality of filter portions 151 is provided on the first surface of the filter portion 15G. The filter portion 151 is arranged at a boundary portion between the Subpixels 10G adjacent in the Y-axis direction in plan view. The plurality of filter portions 152 is provided on the first surface of the filter portion 152. The filter portion 152 is arranged at a boundary portion between the subpixels 10B adjacent in the Y-axis direction in plan view.

The filter portion 151 may be configured to divide the subpixels 10G adjacent in the Y-axis direction in plan view. The filter portion 152 may be configured to divide the subpixels 10B adjacent in the Y-axis direction in plan view.

The filter portions 151 and 152 may have an elongated shape. In a case where the filter portions 151 and 152 have an elongated shape, the longitudinal direction of the elongated shape may substantially coincide with the X-axis direction. The length of the filter portion 151 in the longitudinal direction of the filter portion 151 may be substantially the same as the width of the filter portion 15G in the X-axis direction. The length of the filter portion 152 in the longitudinal direction of the filter portion 152 may be substantially the same as the width of the filter portion 152 in the X-axis direction. Examples of the shape of the elongated filter portions 151 and 152 include a shape similar to the elongated filter portion 150. The shapes of the filter portions 151 and 152 may be the same or different.

The filter portion 151 has a color different from that of the filter portion 15G. Since the filter portion 151 has a color different from that of the filter portion 15G, it is possible to shield light incident on the boundary portion between the subpixels 10G from the light emitting element 12G. Therefore, the viewing angle of the subpixel 10G can be narrowed, and the difference in the viewing angle characteristic between the subpixel 10G and the subpixel 10R can be suppressed.

The filter portion 151 preferably has red of the same color as the filter portion 15R or blue of the same color as the filter portion 15B. Since the filter portion 151 has red of the same color as the filter portion 15R or blue of the same color as the filter portion 15B, the combination of the filter portion 151 and the filter portion 15R or the filter portion 15B can shield light of substantially the entire visible light region at the boundary portion between the subpixels 10G. Therefore, the viewing angle characteristic in the Y-axis direction can be further improved.

Furthermore, since the filter portion 151 has red of the same color as the filter portion 15R or blue of the same color as the filter portion 15B, the filter portion 151 can be formed using the same material as the filter portion 15R or the filter portion 15B. Therefore, the types of materials required for manufacturing the display apparatus 101 can be reduced.

The filter portion 152 has a color different from that of the filter portion 15B. Since the filter portion 152 has a color different from that of the filter portion 15B, it is possible to shield light incident on the boundary portion between the subpixels 10B from the light emitting element 12B. Therefore, the viewing angle of the subpixel 10B can be narrowed, and the difference in the viewing angle characteristic between the subpixel 10B and the subpixel 10R can be suppressed.

The filter portion 152 preferably has red of the same color as the filter portion 15R or green of the same color as the filter portion 15G. Since the filter portion 152 has red of the same color as the filter portion 15R or green of the same color as the filter portion 15G, the combination of the filter portion 151 and the filter portion 15R or the filter portion 15G can shield light of substantially the entire visible light region at the boundary portion between the subpixels 10B. Therefore, the viewing angle characteristic in the Y-axis direction can be further improved.

Furthermore, since the filter portion 151 has red of the same color as the filter portion 15R or green of the same color as the filter portion 15G, the filter portion 152 can be formed using the same material as the filter portion 15R or the filter portion 15G. Therefore, the types of materials required for manufacturing the display apparatus 101 can be reduced.

The filter portion 151 includes a color resist of a color different from that of the filter portion 15G. The filter portion 151 preferably includes a red color resist of the same color as the filter portion 15R or a blue color resist of the same color as the filter portion 15B, and may include the same color resist as the filter portion 15R or the filter portion 15B. The filter portion 152 includes a color resist of a color different from that of the filter portion 15B. The filter portion 152 preferably includes a red color resist of the same color as the filter portion 15R or a green color resist of the same color as the filter portion 15G, and may include the same color resist as the filter portion 15R or the filter portion 15G.

The filter portions 151 and 152 described above are formed as follows. After the formation of the filter portions 15R, 15G, and 15B, a color resist of a color different from that of the filter portion 15G is applied onto the first surface of the filter portions 15R, 15G, and 15B, and after pattern exposure by irradiation with ultraviolet rays through a photomask, development is performed, so that the plurality of filter portions 151 is formed respectively at the boundary portions between the subpixels 10G. Next, a color resist having a color different from that of the filter portion 15B is applied onto the first surface of the filter portions 15R, 15G, and 15B, and after pattern exposure by irradiation with ultraviolet rays through a photomask, development is performed, whereby each of the plurality of filter portions 152 is formed at a boundary portion between the subpixels 10B.

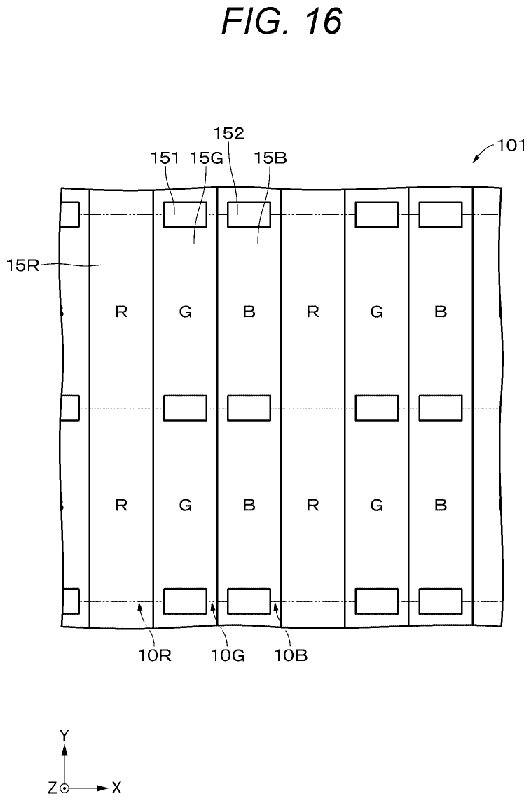

The configuration of the filter portions 151 and 152 is not limited to the above example, and for example, as illustrated in FIG. 16, the subpixels 10G adjacent in the Y-axis direction may be partially connected in a plan view. That is, the length of the filter portion 151 in the X-axis direction may be shorter than the width of the filter portion 15G in the X-axis direction. Similarly, as illustrated in FIG. 16, subpixels 10B adjacent to each other in the Y-axis direction in a plan view may be partially connected to each other. That is, the length of the filter portion 152 in the X-axis direction may be shorter than the width of the filter portion 15B in the X-axis direction.

### Modification 4

In the first embodiment, an example in which the filter portion 150 is provided on the first surface of the filter portion 15G and the first surface of the filter portion 15B has been described (see FIGS. 5 and 6). However, the configuration of the color filter 15 is not limited to this example.

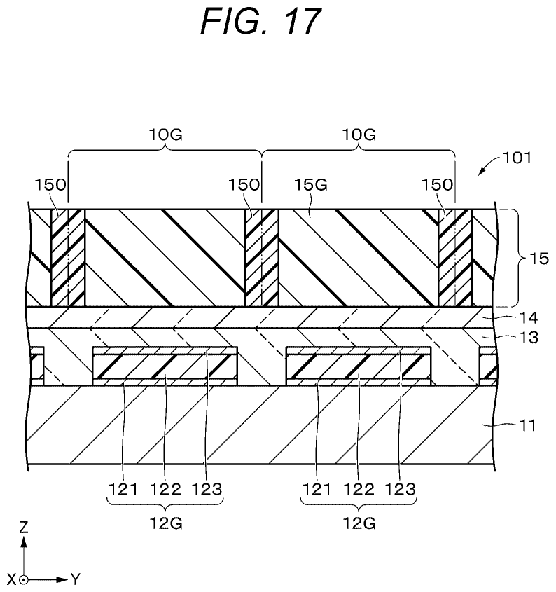

For example, as illustrated in FIG. 17, the filter portion 150 may be provided in the filter portion 15G and the filter portion 15B. In this case, the bottom portion of the filter portion 150 may be located on the first surface of the planarization layer 14, and the top portion of the filter portion 150 may have substantially the same height as the first surface of the filter portion 15G and/or the first surface of the filter portion 15B. That is, the thickness of the filter portion 150 may be substantially the same as the thickness of the filter portion 15G and/or the filter portion 15B. In the present specification, “and/or” means at least one of them, and for example, in the case of “X and/or Y”, it means three ways of only X, only Y, and X and Y.

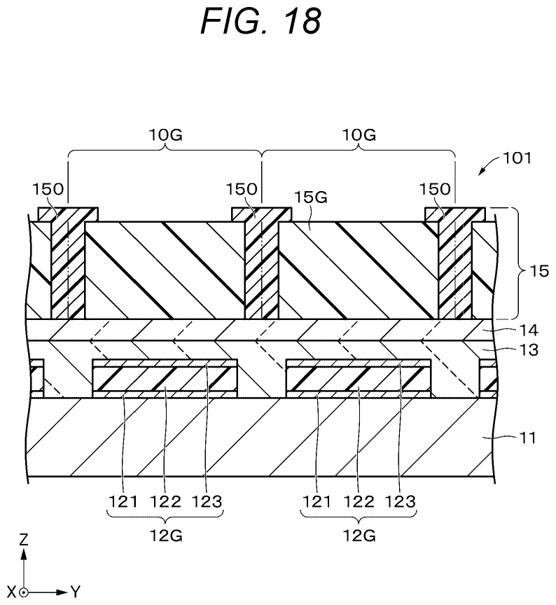

For example, as illustrated in FIG. 18, the bottom portion of the filter portion 150 may be located on the first surface of the planarization layer 14, and the height of the top portion of the filter portion 150 may be higher than the height of the first surface of the filter portion 15G and/or the height of the first surface of the filter portion 15B. That is, the thickness of the filter portion 150 may be thicker than the thickness of the filter portion 15G and/or the thickness of the filter portion 15B. The top portion of the filter portion 150 may protrude on the first surface of the filter portion 15G and/or the first surface of the filter portion 15B.

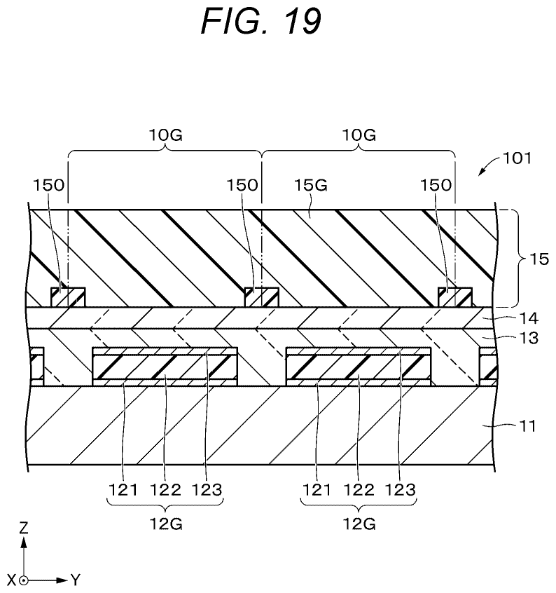

For example, as illustrated in FIG. 19, the bottom portion of the filter portion 150 may be located on the first surface of the planarization layer 14, and the height of the top portion of the filter portion 150 may be lower than the height of the first surface of the filter portion 15G and/or the height of the first surface of the filter portion 15B. That is, the thickness of the filter portion 150 may be thinner than the thickness of the filter portion 15G and/or the thickness of the filter portion 15B. The top portion of the filter portion 150 may be covered with the filter portion 15G and/or the filter portion 15B.

In the above description, a modification of the filter portion 150 in the first embodiment has been described. However, the configuration of Modification 4 may be applied to the filter portion 150 in the second embodiment. Furthermore, the configuration of Modification 4 described above may be applied to the filter portion 150a in Modification 1 and Modification 2, or may be applied to the filter portions 151 and 152 in Modification 3.

### Modification 5

In the first embodiment, an example in which the color conversion layer (color filter 15) includes the plurality of filter portions 15R, the plurality of filter portions 15G, the plurality of filter portions 15B, and the plurality of filter portions 150 has been described. However, the configuration of the color conversion layer is not limited to this example. For example, the color conversion layer may include at least one of a plurality of first wavelength conversion sections, a plurality of second wavelength conversion sections, or a plurality of third wavelength conversion sections instead of at least one of the plurality of filter portions 15R, the plurality of filter portions 15G, or the plurality of filter portions 15B. In Modification 8, the light emitting elements 12 included in the subpixel 10R, the subpixel 10G, and the subpixel 10B may be configured to be able to emit light of the same color. For example, the light emitting element 12 included in the subpixel 10R, the subpixel 10G, and the subpixel 10B may be the light emitting element 12B configured to be able to emit blue light.

The first wavelength conversion section is included in the subpixel 10R instead of the filter portion 15R. The first wavelength conversion section can convert light emitted from the light emitting element 12 of the subpixel 10R into red light and emit the red light. The second wavelength conversion section is included in the subpixel 10G instead of the filter portion 15G. The second wavelength conversion section can convert the light emitted from the light emitting element 12 of the subpixel 10G into green light and emit the green light. The third wavelength conversion section is included in the subpixel 10B instead of the filter portion 15B. The third wavelength conversion section can convert the light emitted from the light emitting element 12 of the subpixel 10B into blue light and emit the blue light. Wavelength conversion in the first wavelength conversion section, the second wavelength conversion section, and the third wavelength conversion section may be either up-conversion or down-conversion.

In a case where the light emitting element 12 included in the subpixel 10R, the subpixel 10G, and the subpixel 10B is the light emitting element 12B configured to be able to emit blue light, the subpixel 10B may include the filter portion 15B instead of the third wavelength conversion section, or may include neither the filter portion 15B nor the third wavelength conversion section.

The first wavelength conversion section, the second wavelength conversion section, and the third wavelength conversion section contain an up-conversion material or a down-conversion material. Specifically, the first wavelength conversion section, the second wavelength conversion section, and the third wavelength conversion section include, for example, quantum dots (semiconductor particles).

In the above description, an example has been described in which the color conversion layer includes at least one of the plurality of first wavelength conversion sections, the plurality of second wavelength conversion sections, or the plurality of third wavelength conversion sections instead of at least one of the plurality of filter portions 15R, the plurality of filter portions 15G, or the plurality of filter portions 15B. However, the configuration of the color conversion layer is not limited thereto, and the color conversion layer may include a plurality of first wavelength conversion sections, a plurality of second wavelength conversion sections, and a plurality of third wavelength conversion sections together with at least one of the plurality of filter portions 15R, the plurality of filter portions 15G, or the plurality of filter portions 15B.

For example, the color conversion layer may include both the filter portion 15R and the first wavelength conversion section, and in this case, the filter portion 15R may be provided above the first wavelength conversion section. The color conversion layer may include both the filter portion 15G and the second wavelength conversion section, and in this case, the filter portion 15G may be provided above the second wavelength conversion section. The color conversion layer may include both the filter portion 15B and the third wavelength conversion section, and in this case, the filter portion 15B may be provided above the third wavelength conversion section.

In the above description, a modification of the wavelength conversion layer (filter portion 150) in the first embodiment has been described, but the configuration of Modification 5 may be applied to the wavelength conversion layer (filter portion 150) in the second embodiment. Furthermore, the configuration of Modification 5 described above may be applied to the wavelength conversion layer (filter portion 150) in Modifications 1 to 4.

### Modification 6

In the first embodiment and the second embodiment, an example in which the color filter 15 is an on-chip color filter has been described. However, the configurations of the display apparatuses 101 and 102 are not limited to this example. For example, the display apparatuses 101 and 102 may include a filling resin layer, a color filter 15, and a substrate in this order on the protective layer 13.

The filling resin layer contains, for example, a cured product of a curable resin. The curable resin includes, for example, at least one selected from the group consisting of a thermosetting resin, an ultraviolet curable resin, and the like. Note that the filling resin layer is not limited to the thermosetting resin and the ultraviolet curable resin, and may contain a kind of curable resin other than the thermosetting resin and the ultraviolet curable resin.

The substrate seals the first surface of the drive substrate 11 on which the plurality of light emitting elements 12 and the like are provided. The substrate has light-transmitting properties with respect to light of each color emitted from the color filter 15. The substrate is, for example, a glass substrate.

The display apparatus 101 having the above configuration is manufactured, for example, as follows. The color filter 15 is formed on the second surface of the substrate. After the protective layer 13 is formed on the first surface of the drive substrate 11 so as to cover the plurality of light emitting elements 12, a filling resin is applied to the first surface of the protective layer 13, and the substrate is placed on the filling resin so that the color filter 15 is on the filling resin side. After the placement, the drive substrate 11 and the substrate are bonded to each other via the filling resin, for example, by applying heat to the filling resin or irradiating the filling resin with ultraviolet rays to cure the filling resin. As a result, the display apparatus 101 is sealed. Note that, in a case where the filling resin contains both the thermosetting resin and the ultraviolet curable resin, the filling resin may be irradiated with ultraviolet rays to be temporarily cured, and then heat may be applied to the filling resin to be finally cured.

### Modification 7

In the first embodiment, an example in which the color filter 15 includes the plurality of filter portions 150 has been described. However, the configuration of the color filter 15 is not limited to this example. For example, the color filter 15 may include a black light shielding portion instead of the plurality of filter portions 150. Similarly, the color filter 15 in the second embodiment may include a black light shielding portion instead of the plurality of filter portions 150. The color filter 15 in Modifications 1 and 2 may include a black light shielding portion instead of the plurality of filter portions 150 and the plurality of filter portions 150a. The color filter 15 in Modification 3 may include a black light shielding portion instead of the plurality of filter portions 150 and the plurality of filter portions 151 and 152.

### Modification 8

In the first embodiment, the example in which the OLED layer 122 and the second electrode 123 are divided between the light emitting elements 12 adjacent in the in-plane direction of the first surface of the drive substrate 11 has been described. However, the configurations of the OLED layer 122 and the second electrode 123 are not limited to this example. For example, as illustrated in FIG. 20, the OLED layer 122 may be a layer that is connected between the light emitting elements 12 adjacent in the in-plane direction of the first surface of the drive substrate 11 and is common to the plurality of light emitting elements 12. Similarly, the second electrode 123 may be connected between the light emitting elements 12 adjacent in the in-plane direction of the first surface of the drive substrate 11, and may be an electrode common to the plurality of light emitting elements 12.

In the above description, a modification of the OLED layer 122 and the second electrode 123 in the first embodiment has been described, but the configuration of Modification 5 may be applied to the OLED layer 122 and the second electrode 123 in the second embodiment.

### Modification 9

In the first embodiment and the second embodiment, an example in which the light emitting elements 12R, 12G, and 12B include the OLED layer 122 capable of emitting white light has been described. However, the configurations of the light emitting elements 12R, 12G, and 12B are not limited to this example. For example, the light emitting element 12R may include an OLED layer 122 capable of emitting red light, the light emitting element 12G may include an OLED layer 122 capable of emitting green light, and the light emitting element 12B may include an OLED layer 122 capable of emitting blue light. In this case, the light emitting elements 12R, 12G, and 12B may or may not have a resonator structure.

### Modification 10

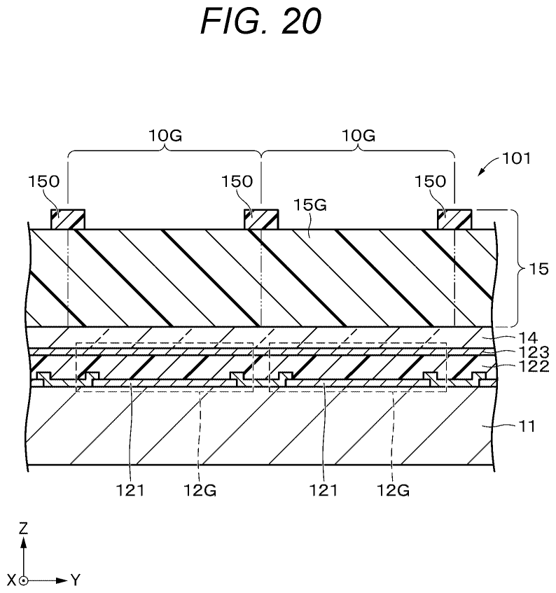

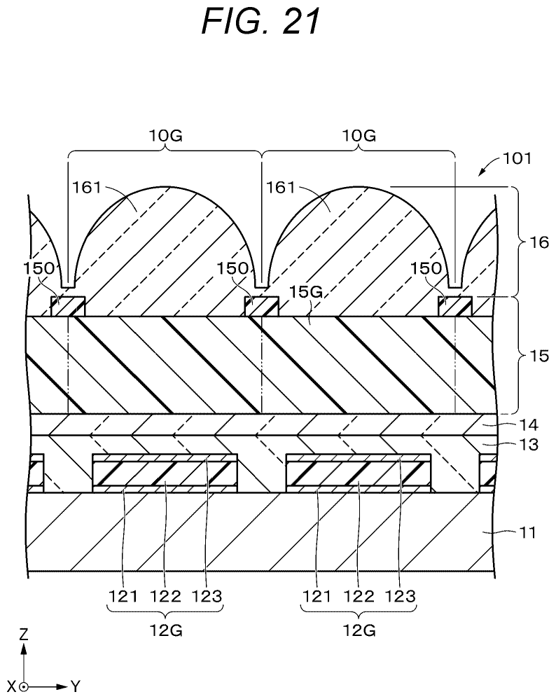

As illustrated in FIG. 21, the display apparatus 101 according to the first embodiment may further include a lens array 16. The lens array 16 is provided on the first surface of the color filter 15. A planarization layer may be provided between the color filter 15 and the lens array 16. The lens array 16 includes a plurality of lenses 161. The lens 161 can condense the light emitted upward from the light emitting element 12 in the front direction. The plurality of lenses 161 is so-called on-chip microlenses (OCL), and is two-dimensionally arranged on the first surface of the color filter 15 in a specified array. The specified array may be an array similar to the subpixel 10 in the first embodiment.

One lens 161 may be provided above one light emitting element 12, or two or more lenses 161 may be provided above one light emitting element 12. FIG. 21 illustrates an example in which one lens 161 is provided above one light emitting element 12. The lens 161 may have a curved surface on the emission surface side from which the light incident from the light emitting element 12 is emitted. The curved surface is preferably a convex curved surface protruding in a direction away from the light emitting element 12, but is not limited to the convex curved surface. Examples of the curved surface include, but are not limited to, a substantially parabolic shape, a substantially hemispherical shape, and a substantially semielliptical shape.

The lens array 16 includes, for example, an inorganic material or an organic material having light-transmitting properties with respect to light emitted from the light emitting element 12. The inorganic material includes, for example, silicon oxide (SiOₓ). The organic material may be a polymer resin. The organic material includes, for example, a photosensitive resin such as an ultraviolet curable resin.

In the above description, an example in which the display apparatus 101 according to the first embodiment includes the lens array 16 has been described, but the display apparatus 102 according to the second embodiment may include the lens array 16.

### Modification 11

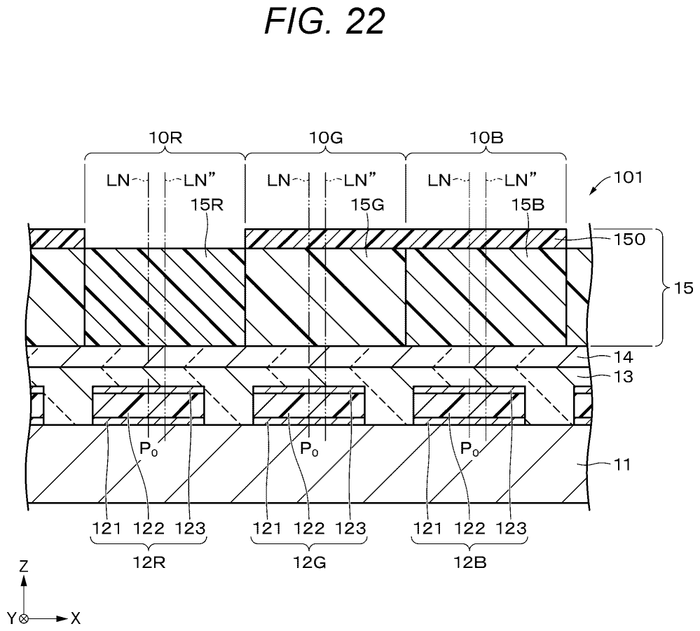

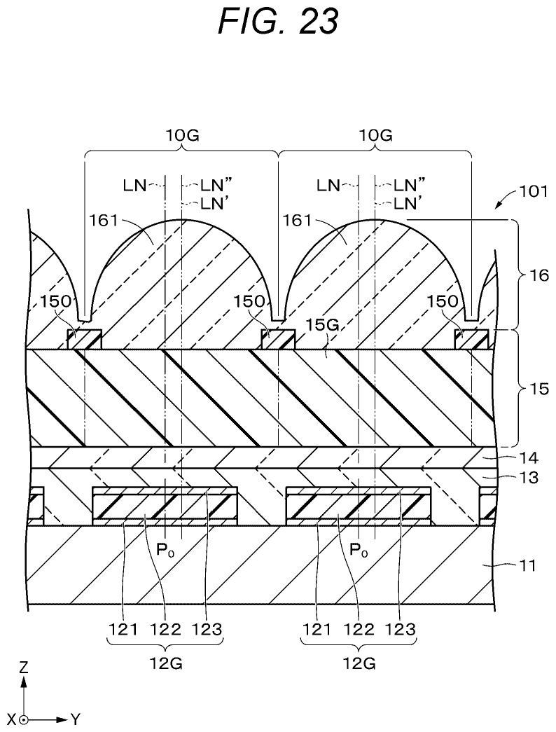

FIG. 22 is an enlarged XZ cross-sectional view illustrating a part of the effective pixel region RE1. FIG. 23 is an enlarged YZ cross-sectional view illustrating a part of the effective pixel region RE1. As illustrated in FIGS. 22 and 23, at least a part of the filter portions 15R, 15G, and 15B among the plurality of filter portions 15R, 15G, and 15B, and at least a part of the filter portions 150 among the plurality of filter portions 150 may be shifted in the in-plane direction of the first surface of the drive substrate 11 with reference to the center position Po of the light emitting element 12. Since the filter portions 15R, 15G, and 15B and the filter portion 150 are shifted in the in-plane direction in this manner, the emission direction of the light from the subpixel 10 can be controlled. A shift direction of the color filter 15 is selected according to desired display characteristics. Here, the center position P₀ of the light emitting element 12 represents a geometric center position of the light emitting element 12 in plan view.

In a case where the display apparatus 101 includes the lens array 16, at least some lenses 161 of the plurality of lenses 161 may be shifted in the in-plane direction of the first surface of the drive substrate 11 with reference to the center position P₀ of the light emitting element 12. Since the lens 161 is shifted in the in-plane direction in this manner, the emission direction of the light from the subpixel 10 can be controlled.

Details of the shifts of the filter portions 15R, 15G, and 15B, the filter portion 150, and the lens 161 will be described in <6 Relationship Between Normal Lines Passing Through Centers of Light Emitting Section, Lens Member, and Wavelength Selection Section>.

In the above description, a modification of the display apparatus 101 according to the first embodiment has been described. However, the configuration of the modification may be applied to the display apparatus 102 according to the second embodiment, or may be applied to the display apparatuses 101 and 102 according to Modifications 1 to 10 and 12. Specifically, for example, the present invention may be applied to the filter portion 150a in Modification 1 and Modification 2, or may be applied to the filter portions 151 and 152 in Modification 3.

### Modification 12

In the first embodiment and the second embodiment, an example in which the light emitting element 12 is an OLED element has been described. However, the light emitting element is not limited to this example, and may be, for example, a self-luminous light emitting element such as a light emitting diode (LED), an inorganic electro-luminescence (IEL) element, a quantum dot light emitting diode (QLED), or a semiconductor laser element. Two or more kinds of light emitting elements may be provided in the display apparatus.

### Modification 13

In the first embodiment and the second embodiment, an example in which the display apparatuses 101 and 102 include pixels of three colors has been described. However, the pixel configuration of the display apparatuses 101 and 102 is not limited to this example, and the display apparatuses 101 and 102 may include pixels of two colors or four or more colors.

### Modification 14

The display apparatuses 101 and 102 according to the first embodiment and the second embodiment may include a light emitting element 12 capable of emitting white light instead of the plurality of light emitting elements 12R, 12G, and 12B.

### Other Modifications

Although the first embodiment, the second embodiment, and the modifications (hereinafter referred to as a “first embodiment and the like”) of the first embodiment and the second embodiment of the present disclosure have been specifically described above, the present disclosure is not limited to the first embodiment and the like, and various modifications based on the technical idea of the present disclosure can be made.

For example, the configurations, methods, steps, shapes, materials, numerical values, and the like mentioned in the first embodiment and the like are merely examples, and different configurations, methods, steps, shapes, materials, numerical values, and the like may be used as necessary.

The configurations, methods, steps, shapes, materials, numerical values, and the like of the first embodiment and the like can be combined with each other without departing from the gist of the present disclosure.

The materials exemplified in the first embodiment and the like can be used alone or in combination of two or more unless otherwise specified.

Further, the present disclosure can adopt the following configurations.
(1)

A display apparatus including:
a plurality of first pixels capable of emitting light of a first color; and
a plurality of second pixels capable of emitting light of a second color,
in which
the plurality of second pixels constitutes a plurality of columns, and
a column of the second pixels includes:
a plurality of first light emitting elements arranged in a column direction of a column of the second pixels;
a first filter portion provided above the plurality of first light emitting elements and having the second color; and
a plurality of second filter portions provided above the plurality of first light emitting elements and at respective boundary portions between the second pixels adjacent in the column direction, the plurality of second filter portions having a color different from the second color.
(2)

The display apparatus according to (1), in which
the second filter portion is provided on the first filter portion.
(3)

The display apparatus according to (1), in which
the second filter portion is provided in the first filter portion.
(4)

The display apparatus according to (3), in which
a thickness of the second filter portion is substantially same as a thickness of the first filter portion.
(5)

The display apparatus according to (3), in which
the first filter portion has a surface on a side opposite to a side of the first light emitting element, and
a part of the second filter portion protrudes on the surface of the first filter portion.
(6)

The display apparatus according to (3), in which
the first filter portion covers the second filter portion.
(7)

The display apparatus according to any one of (1) to (6), in which
the column of the second pixels further includes a plurality of lenses provided above the plurality of first light emitting elements.
(8)

The display apparatus according to any one of (1) to (7), in which
at least a part of the plurality of second filter portions is shifted in an in-plane direction with reference to the first light emitting element.
(9)

The display apparatus according to any one of (1) to (8), in which
a size of the second pixel in the column direction is larger than a size of the first pixel in the column direction.
(10)

The display apparatus according to any one of (1) to (9), in which
the first color includes red, and
the first pixel has a resonator structure.
(11)

The display apparatus according to any one of (1) to (10), further including
a plurality of third pixels capable of emitting light of a third color.
(12)

The display apparatus according to (11), in which
the second filter portion has the first color or the third color.
(13)

The display apparatus according to (11) or (12), in which
the first color, the second color, and the third color are different from each other,
the first color, the second color, and the third color are each one color selected from a group including red, blue, and green, and
tristimulus values X, Y, and Z of the CIE1931 color system obtained by measuring a white image displayed on the display apparatus from the column direction are substantially equal.
(14)

The display apparatus according to any one of (11) to (13), in which
the plurality of third pixels constitutes a plurality of columns, and
a column of the third pixels includes:
a plurality of second light emitting elements arranged in the column direction;
a third filter portion provided above the plurality of second light emitting elements and having the third color; and
a plurality of fourth filter portions provided above the plurality of second light emitting elements and at respective boundary portions between the third pixels adjacent in the column direction, the plurality of fourth filter portions having a color different from the third color.
(15)

The display apparatus according to any one of (11) to (14), in which
the first pixel, the second pixel, and the third pixel are arranged in a stripe array.
(16)

The display apparatus according to any one of (11) to (14), in which
the first pixel, the second pixel, and the third pixel are arranged in a square array, and
the second pixel is arranged adjacent to the first pixel and the third pixel.
(17)

The display apparatus according to any one of (1) to (16), in which
the column of the second pixels further includes a fifth filter portion provided in the second pixel in plan view and having a color different from the second color.
(18)

The display apparatus according to any one of (1) to (17), in which
the plurality of first light emitting elements is configured to emit white light or light of the second color.
(19)

A display apparatus including:
a plurality of first pixels capable of emitting light of a first color; and
a plurality of second pixels capable of emitting light of a second color,
in which
the plurality of second pixels constitutes a plurality of columns, and
a column of the second pixels includes:
a plurality of first light emitting elements arranged in a column direction of a column of the second pixels;
a color conversion section provided above the plurality of first light emitting elements and capable of converting light emitted from the plurality of first light emitting elements into light of the second color; and
a plurality of filter portions provided above the plurality of first light emitting elements and at respective boundary portions between the second pixels adjacent in the column direction, the plurality of filter portions having a color different from the second color.
(20)

An electronic device including the display apparatus according to any one of (1) to (19).

### 5 Simulation

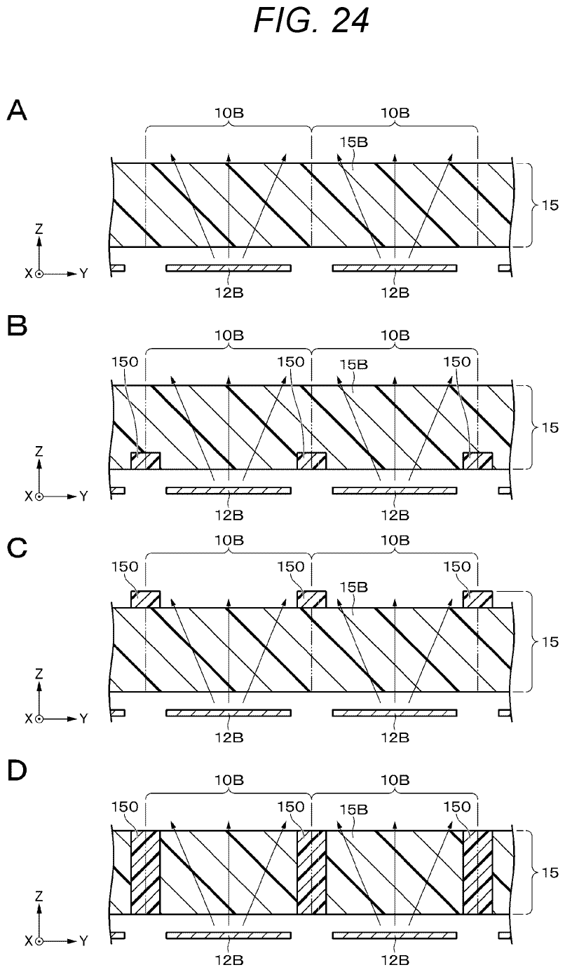

Hereinafter, the present disclosure will be specifically described by simulation, but the present disclosure is not limited to these simulations. Note that, in the analysis model illustrated in FIGS. 24A to 24D, portions corresponding to the display apparatus 101 according to the first embodiment are denoted by the same reference signs.

### Simulation 1

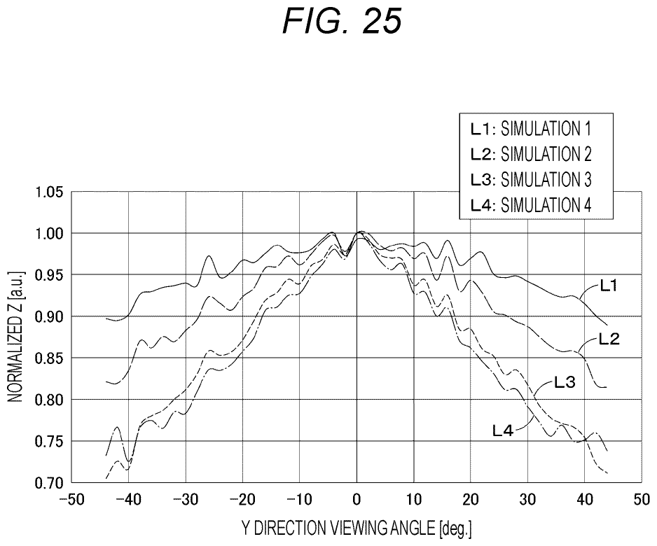

The configuration illustrated in FIG. 24A was set as an analysis model, and the viewing angle characteristic of the Z value of the tristimulus values was obtained. The results are illustrated in FIG. 25 (curve L1).

### Simulation 2

The configuration illustrated in FIG. 24B was set as an analysis model, and the viewing angle characteristic of the Z value of the tristimulus values was obtained. The results are illustrated in FIG. 25 (curve L2).

### Simulation 3

The configuration illustrated in FIG. 24C was set as an analysis model, and the viewing angle characteristic of the Z value of the tristimulus values was obtained. The results are illustrated in FIG. 25 (curve L3).

### Simulation 4

The configuration illustrated in FIG. 24D was set as an analysis model, and the viewing angle characteristic of the Z value of the tristimulus values was obtained. The results are illustrated in FIG. 25 (curve L4).

The results of the simulation 1 to 4 indicate the following.

By providing the filter portion 150 between the subpixels 10B adjacent in the Y-axis direction, the viewing angle of the Z value of the tristimulus values can be narrowed.

The viewing angle characteristic of the Z value of the tristimulus values can be changed by the arrangement position and thickness of the filter portion 150.

### 6 Relationship between Normal Lines Passing Through Centers of Light Emitting Section, Lens Member, and Wavelength Selection Section

Hereinafter, a relationship between a normal line LN passing through the center of the light emitting section, a normal line LN′ passing through the center of the lens member, and a normal line LN″ passing through the center of the wavelength selection section will be described. Here, the light emitting section is, for example, the light emitting element 12 in the first embodiment, the second embodiment, modifications thereof, or the like. The lens member is, for example, the lens 161 in Modification 10, Modification 11, or the like. The wavelength selection section is, for example, the filter portions 15R, 15G, and 15B in the first embodiment, the second embodiment, or modifications thereof.

Note that the size of the wavelength selection section may be appropriately changed according to the light emitted from the light emitting section, or in a case where the light absorption section (for example, black matrix section) is provided between the wavelength selection sections of adjacent light emitting sections, the size of the light absorption section may be appropriately changed according to the light emitted from the light emitting section. In addition, the size of the wavelength selection section may be appropriately changed according to the distance (offset amount) do between the normal line passing through the center of the light emitting section and the normal line passing through the center of the wavelength selection section. The planar shape of the wavelength selection section may be the same as, similar to, or different from the planar shape of the lens member.

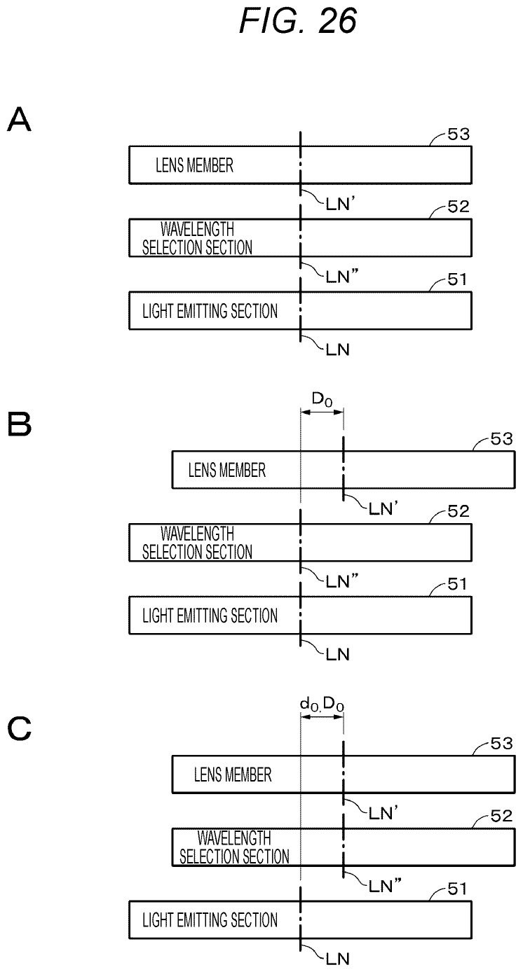

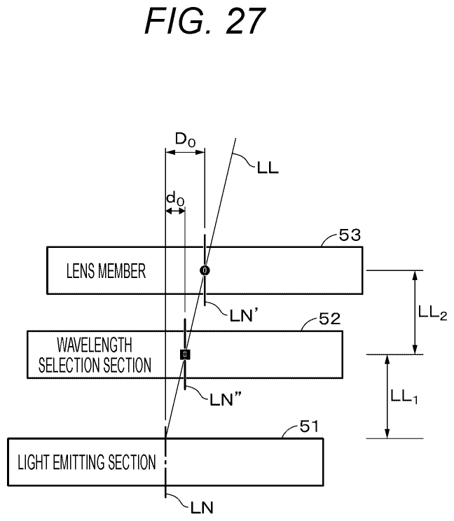

Hereinafter, with reference to FIGS. 26A, 26B, 26C, and 27, a relationship of a normal line passing through the center of each section in a case where the light emitting section 51, the wavelength selection section 52, and the lens member 53 are arranged in this order will be described.

As illustrated in FIG. 26A, a normal line LN passing through the center of the light emitting section 51, a normal line LN″ passing through the center of the wavelength selection section 52, and a normal line LN′ passing through the center of the lens member 53 may coincide with each other. That is, D₀=0 and d₀=0 may be satisfied. Here, D₀ represents a distance (offset amount) between the normal line LN passing through the center of the light emitting section 51 and the normal line LN′ passing through the center of the lens member 53, and d₀ represents a distance (offset amount) between the normal line LN passing through the center of the light emitting section 51 and the normal line LN″ passing through the center of the wavelength selection section 52.

As illustrated in FIG. 26B, although the normal line LN passing through the center of the light emitting section 51 and the normal line LN″ passing through the center of the wavelength selection section 52 coincide with each other, the configuration may be such that the normal line LN passing through the center of the light emitting section 51 and the normal line LN″ passing through the center of the wavelength selection section 52 do not coincide with the normal line LN′ passing through the center of the lens member 53. That is, D₀>0 and d₀=0 may be satisfied.

As illustrated in FIG. 26C, the configuration may be such that the normal line LN passing through the center of the light emitting section 51 does not coincide with the normal line LN″ passing through the center of the wavelength selection section 52 and the normal line LN′ passing through the center of the lens member 53, whereas the normal line LN″ passing through the center of the wavelength selection section 52 and the normal line LN′ passing through the center of the lens member 53 coincide with each other. That is, D₀>0, d₀>0, and D₀=d₀ may be satisfied.

As illustrated in FIG. 27, the normal line LN passing through the center of the light emitting section 51, the normal line LN″ passing through the center of the wavelength selection section 52, and the normal line LN′ passing through the center of the lens member 53 may not coincide with each other. That is, D₀>0, d₀>0, and D₀≠d₀ may be satisfied. Here, the center of the wavelength selection section 52 (a position indicated by a black square in FIG. 27) is preferably located on a straight line LL connecting the center of the light emitting section 51 and the center of the lens member 53 (a position indicated by a black circle in FIG. 27). Specifically, when the distance in the thickness direction (vertical direction in FIG. 27) between the center of the light emitting section 51 and the center of the wavelength selection section 52 is defined as LL₁, and the distance in the thickness direction between the center of the wavelength selection section 52 and the center of the lens member 53 is defined as LL₂,
it is preferable that

D₀>d₀>0
and, in consideration of manufacturing variations, the following relationship be satisfied:

d₀:D₀=LL₁:(LL₁+LL₂)l

Here, the thickness direction represents the thickness direction of the light emitting section 51, the wavelength selection section 52, and the lens member 53.

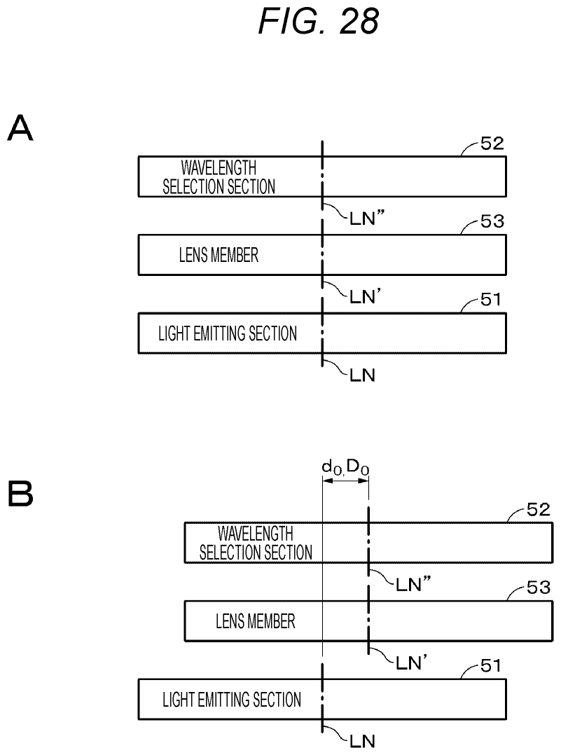

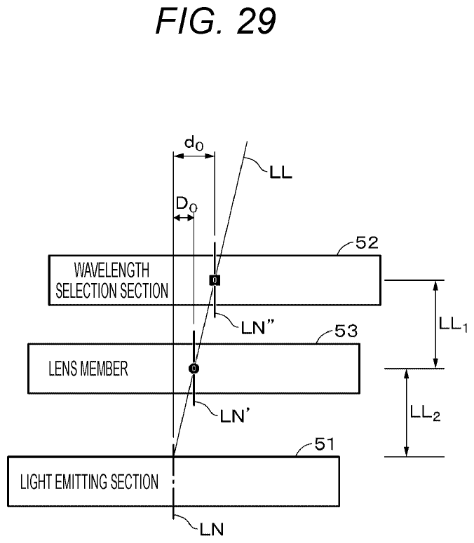

Hereinafter, with reference to FIGS. 28A, 28B, and 29, a relationship of a normal line passing through the center of each section in a case where the light emitting section 51, the lens member 53, and the wavelength selection section 52 are arranged in this order will be described.

As illustrated in FIG. 28A, a normal line LN passing through the center of the light emitting section 51, a normal line LN″ passing through the center of the wavelength selection section 52, and a normal line LN′ passing through the center of the lens member 53 may coincide with each other. That is, D₀>0 and d₀=0 may be satisfied.

As illustrated in FIG. 28B, the configuration may be such that the normal line LN passing through the center of the light emitting section 51 does not coincide with the normal line LN″ passing through the center of the wavelength selection section 52 and the normal line LN′ passing through the center of the lens member 53, whereas the normal line LN″ passing through the center of the wavelength selection section 52 and the normal line LN′ passing through the center of the lens member 53 coincide with each other. That is, D₀>0, d₀>0, and D₀=d₀ may be satisfied.

As illustrated in FIG. 29, the normal line LN passing through the center of the light emitting section 51, the normal line LN″ passing through the center of the wavelength selection section 52, and the normal line LN′ passing through the center of the lens member 53 may not coincide with each other. Here, the center of the lens member 53 (a position indicated by a black circle in FIG. 29) is preferably located on a straight line LL connecting the center of the light emitting section 51 and the center of the wavelength selection section 52 (a position indicated by a black square in FIG. 29). Specifically, when the distance in the thickness direction (vertical direction in FIG. 29) between the center of the light emitting section 51 and the center of the lens member 53 is defined as LL₂, and the distance in the thickness direction between the center of the lens member 53 and the center of the wavelength selection section 52 is defined as LL₁,
it is preferable that

d₀>D₀>0
and, in consideration of manufacturing variations, the following relationship be satisfied:

D₀:d₀=LL₂:(LL₁+LL₂).

Here, the thickness direction represents the thickness direction of the light emitting section 51, the wavelength selection section 52, and the lens member 53.

The filter portions 150, 150a, 151, and 152 in the first embodiment, the second embodiment, and the modifications thereof may be shifted by the same distance (offset amount) as the wavelength selection section 52 described above in the same direction as the wavelength selection section 52 described above.

### 7 Example of Resonator Structure

The subpixels included in the display apparatus 101 according to the first embodiment, the display apparatus 102 according to the first embodiment, and the display apparatuses 101 and 102 (hereinafter, referred to as a “display apparatus 101 and the like according to the first embodiment”) according to the modifications thereof can be configured to have a resonator structure that causes light generated by a light emitting element to resonate. Hereinafter, a resonator structure will be described with reference to the drawings. Note that, in the following description, the first surface of each layer may be referred to as an upper surface.

### Resonator Structure: First Example

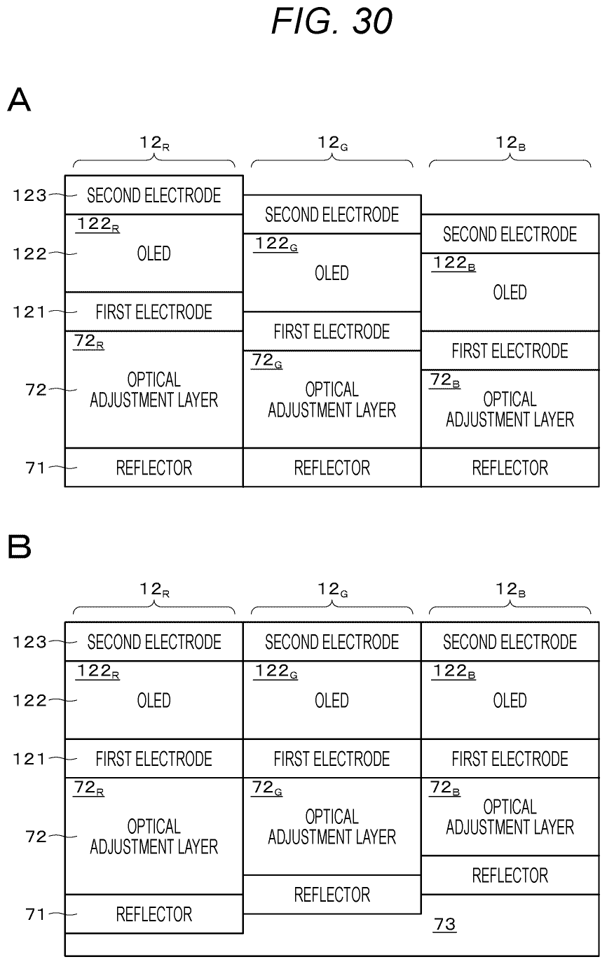

FIG. 30A is a schematic cross-sectional view for explaining a first example of the resonator structure. Furthermore, in the following description, the light emitting elements 12_{R}, 12_{G}, and 12_{B} respectively represent the light emitting elements 12R_{,} 12G, and 12B in the display apparatus 101 and the like according to the first embodiment. Furthermore, the OLED layer 122 of the subpixel 10R, the OLED layer 122 of the subpixel 10G, and the OLED layer 122 of the subpixel 10B may be referred to as an OLED layer 122_{R}, an OLED layer 122_{G}, and an OLED layer 122_{B}, respectively.

In the first example, the first electrode 121 is formed with a common film thickness in each light emitting element 12. It similarly applies to the second electrode 123.

The reflector 71 is disposed below the first electrode 121 of the light emitting element 12 with the optical adjustment layer 72 interposed therebetween. A resonator structure that resonates light generated by the OLED layer 122 is formed between the reflector 71 and the second electrode 123. In the following description, the optical adjustment layers 72 provided corresponding to the subpixels 10R, 10G, and 10B may be referred to as optical adjustment layers 72_{R}, 72_{G}, and 72_{B}, respectively.

The reflector 71 is formed to have a common film thickness in each light emitting element 12. The film thickness of the optical adjustment layer 72 varies depending on the color to be displayed by the subpixel. Since the optical adjustment layers 72_{R}, 72_{G}, and 72_{B} have different film thicknesses, it is possible to set an optical distance at which optimum resonance occurs for a wavelength of light corresponding to a color to be displayed.

In the example illustrated in FIG. 30A, the upper surfaces of the reflectors 71 in the light emitting elements 12_{R}, 12_{G}, and 12_{B} are arranged so as to be aligned. As described above, since the film thickness of the optical adjustment layer 72 varies depending on the color to be displayed by the subpixel, the position of the upper surface of the second electrode 123 varies depending on the types of the light emitting elements 12_{R}, 12_{G}, and 12_{B}.

The reflector 71 can be formed using, for example, a metal such as aluminum (Al), silver (Ag), or copper (Cu), or an alloy containing these as a main component.

The optical adjustment layer 72 can be formed using an inorganic insulating material such as silicon nitride (SiNₓ), silicon oxide (SiOₓ), or silicon oxynitride (SiOₓN_{y}), or an organic resin material such as an acrylic resin or a polyimide resin. The optical adjustment layer 72 may be a single layer or a laminated film of a plurality of materials. Furthermore, the number of laminated layers may be different depending on the type of the light emitting element 12.

The first electrode 121 can be formed using a transparent conductive material such as indium tin oxide (ITO), indium zinc oxide (IZO), or zinc oxide (ZnO).

The second electrode 123 needs to function as a semi-transmission reflection film. The second electrode 123 can be formed using magnesium (Mg), silver (Ag), a magnesium-silver alloy (MgAg) containing these as a main component, an alloy containing an alkali metal or an alkaline earth metal, or the like.

### Resonator Structure: Second Example

FIG. 30B is a schematic cross-sectional view for explaining a second example of the resonator structure.

Also in the second example, the first electrode 121 and the second electrode 123 are formed with a common film thickness in each light emitting element 12.

Then, also in the second example, the reflector 71 is disposed below the first electrode 121 of the light emitting element 12 with the optical adjustment layer 72 interposed therebetween. A resonator structure that resonates light generated by the OLED layer 122 is formed between the reflector 71 and the second electrode 123. Similarly to the first example, the reflector 71 is formed with a common film thickness in each light emitting element 12, and the film thickness of the optical adjustment layer 72 varies depending on the color to be displayed by the subpixel.

In the first example illustrated in FIG. 30A, the upper surfaces of the reflectors 71 in the light emitting elements 12_{R}, 12_{G}, and 12_{B} are arranged so as to be aligned, and the positions of the upper surfaces of the second electrodes 123 are different depending on the types of the light emitting elements 12_{R}, 12_{G}, and 12_{B}.

On the other hand, in the second example illustrated in FIG. 30B, the upper surfaces of the second electrodes 123 are arranged so as to be aligned with the light emitting elements 12_{R}, 12_{G}, and 12_{B}. In order to align the upper surfaces of the second electrodes 123, in the light emitting elements 12_{R}, 12_{G}, and 12_{B}, the upper surfaces of the reflectors 71 are arranged differently according to the types of the light emitting elements 12_{R}, 12_{G}, and 12_{B}. Therefore, the lower surface (in other words, the upper surface of the base layer (insulating layer) 73) of the reflector 71 has a stair shape according to the type of the light emitting element 12.

Materials and the like constituting the reflector 71, the optical adjustment layer 72, the first electrode 121, and the second electrode 123 are similar to the contents described in the first example, and thus the description thereof is omitted.

### Resonator Structure: Third Example

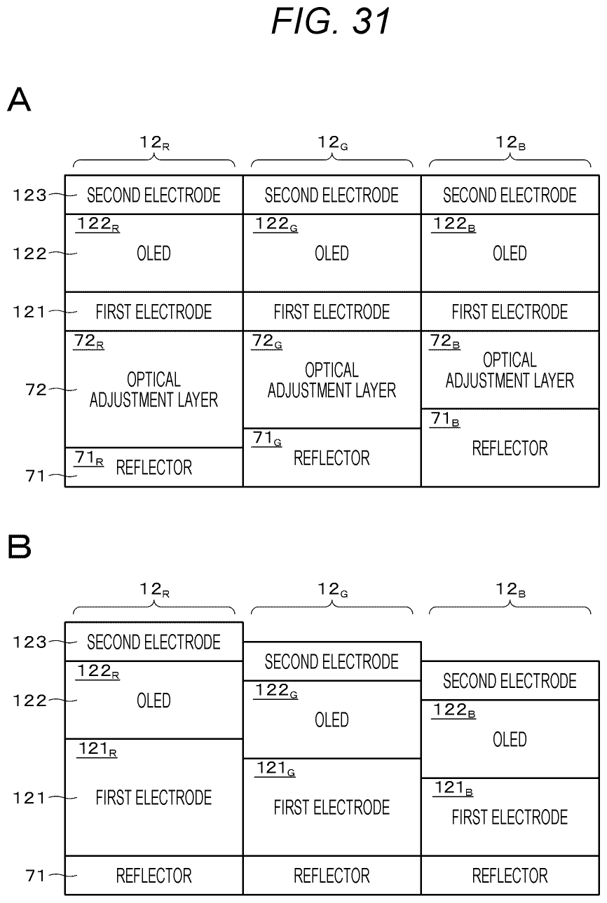

FIG. 31A is a schematic cross-sectional view for explaining a third example of the resonator structure. In the following description, the reflectors 71 provided corresponding to the subpixels 10R, 10G, and 10B may be referred to as reflectors 71_{R}, 71_{G}, and 71_{B}, respectively.

Also in the third example, the first electrode 121 and the second electrode 123 are formed with a common film thickness in each light emitting element 12.

Then, also in the third example, the reflector 71 is disposed below the first electrode 121 of the light emitting element 12 with the optical adjustment layer 72 interposed therebetween. A resonator structure that resonates light generated by the OLED layer 122 is formed between the reflector 71 and the second electrode 123. Similarly to the first example and the second example, the film thickness of the optical adjustment layer 72 varies depending on the color to be displayed by the subpixel. Then, similarly to the second example, the positions of the upper surfaces of the second electrodes 123 are arranged so as to be aligned with the light emitting elements 12_{R}, 12_{G}, and 12_{B}.

In the second example illustrated in FIG. 31B, in order to align the upper surfaces of the second electrodes 123, the lower surfaces of the reflectors 71 have a stair shape according to the type of the light emitting element 12.

On the other hand, in the third example illustrated in FIG. 31A, the film thickness of the reflector 71 is set to be different according to the types of the light emitting elements 12_{R}, 12_{G}, and 12_{B}. More specifically, the film thickness is set such that the lower surfaces of the reflectors 71_{R}, 71_{G}, and 71_{B} are aligned.

Materials and the like constituting the reflector 71, the optical adjustment layer 72, the first electrode 121, and the second electrode 123 are similar to the contents described in the first example, and thus the description thereof is omitted.

### Resonator Structure: Fourth Example

FIG. 31B is a schematic cross-sectional view for explaining a fourth example of the resonator structure. In the following description, the first electrodes 121 provided corresponding to the subpixels 10R, 10G, and 10B may be referred to as first electrodes 121_{R}, 121_{G}, and 121_{B}, respectively.

In the first example illustrated in FIG. 31A, the first electrode 121 and the second electrode 123 of each light emitting element 12 are formed to have a common film thickness. Then, the reflector 71 is disposed below the first electrode 121 of the light emitting element 12 with the optical adjustment layer 72 interposed therebetween.

On the other hand, in the fourth example illustrated in FIG. 31B, the optical adjustment layer 72 is omitted, and the film thickness of the first electrode 121 is set to be different according to the types of the light emitting elements 12_{R}, 12_{G}, and 12_{B}.

The reflector 71 is formed to have a common film thickness in each light emitting element 12. The film thickness of the first electrode 121 varies depending on the color to be displayed by the subpixel. Since the first electrodes 121_{R}, 121_{G}, and 121_{B} have different film thicknesses, it is possible to set an optical distance that generates optimum resonance for the wavelength of light according to the color to be displayed.

Materials and the like constituting the reflector 71, the optical adjustment layer 72, the first electrode 121, and the second electrode 123 are similar to the contents described in the first example, and thus the description thereof is omitted.

### Resonator Structure: Fifth Example

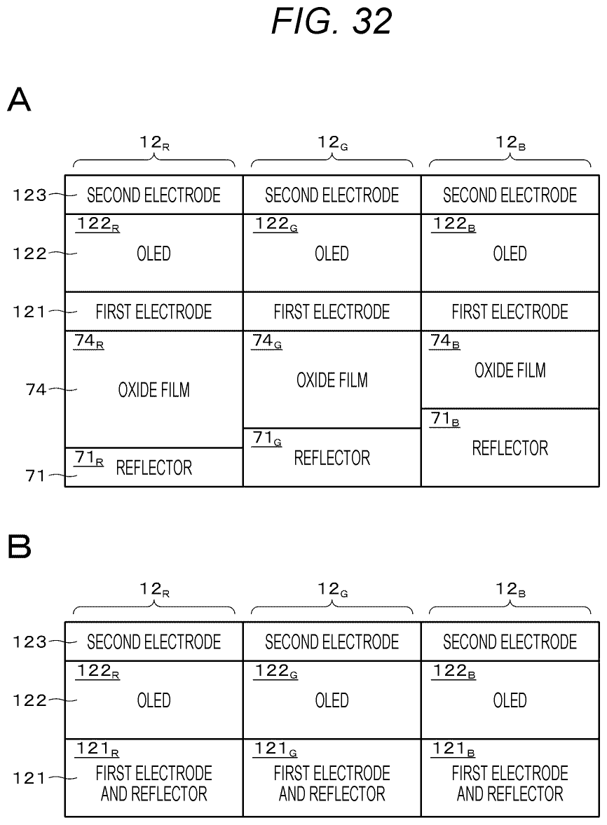

FIG. 32A is a schematic cross-sectional view for explaining a fifth example of the resonator structure.

In the first example illustrated in FIG. 30A, the first electrode 121 and the second electrode 123 are formed to have a common film thickness in each light emitting element 12. Then, the reflector 71 is disposed below the first electrode 121 of the light emitting element 12 with the optical adjustment layer 72 interposed therebetween.

On the other hand, in the fifth example illustrated in FIG. 32A, the optical adjustment layer 72 is omitted, and instead, the oxide film 74 is formed on the surface of the reflector 71. The film thickness of the oxide film 74 was set to be different according to the types of the light emitting elements 12_{R}, 12_{G}, and 12_{B}. In the following description, the oxide films 74 provided corresponding to the subpixels 10R, 10G, and 10B may be referred to as oxide films 74_{R}, 74_{G}, and 74_{B}, respectively.

The film thickness of the oxide film 74 varies depending on the color to be displayed by the subpixel. Since the oxide films 74_{R}, 74_{G}, and 74_{B} have different film thicknesses, it is possible to set an optical distance at which optimum resonance occurs for a wavelength of light corresponding to a color to be displayed.

The oxide film 74 is a film obtained by oxidizing the surface of the reflector 71, and is constituted by, for example, aluminum oxide, tantalum oxide, titanium oxide, magnesium oxide, zirconium oxide, or the like. The oxide film 74 functions as an insulating film for adjusting an optical path length (optical distance) between the reflector 71 and the second electrode 123.

The oxide film 74 having different film thicknesses depending on the types of the light emitting elements 12_{R}, 12_{G}, and 12_{B} can be formed, for example, as follows.

First, the electrolytic solution is filled in the container, and the substrate on which the reflector 71 is formed is immersed in the electrolytic solution. Further, the electrode is disposed so as to face the reflector 71.

Then, a positive voltage is applied to the reflector 71 with reference to the electrode, and the reflector 71 is anodized. The film thickness of the oxide film due to the anodization is proportional to the voltage value with respect to the electrode. Therefore, anodization is performed in a state where a voltage corresponding to the type of the light emitting element 12 is applied to each of the reflectors 71_{R}, 71_{G}, and 71_{B}. As a result, the oxide films 74 having different film thicknesses can be collectively formed.

Materials and the like constituting the reflector 71, the first electrode 121, and the second electrode 123 are similar to the contents described in the first example, and thus description thereof is omitted.

### Resonator Structure: Sixth Example

FIG. 32B is a schematic cross-sectional view for explaining a sixth example of the resonator structure.

In the sixth example, the light emitting element 12 is configured by laminating a first electrode 121, an OLED layer 122, and a second electrode 123. However, in the sixth example, the first electrode 121 is formed to function as both an electrode and a reflector. The first electrode (also serving as a reflector) 121 is constituted by a material having an optical constant selected according to the type of the light emitting elements 12_{R}, 12_{G}, and 12_{B}. Since the phase shift by the first electrode (also serving as a reflector) 121 is different, it is possible to set an optical distance that generates optimum resonance for the wavelength of light according to the color to be displayed.

The first electrode (also serving as a reflector) 121 can be constituted by a single metal such as aluminum (Al), silver (Ag), gold (Au), or copper (Cu), or an alloy containing these as a main component. For example, the first electrode (also serving as a reflector) 121_{R} of the light emitting element 12_{R} may be constituted by copper (Cu), and the first electrode (also serving as a reflector) 121_{G} of the light emitting element 12_{G} and the first electrode (also serving as a reflector) 121_{B} of the light emitting element 12_{B} may be constituted by aluminum.

The material and the like constituting the second electrode 123 are similar to the contents described in the first example, and thus the description thereof will be omitted.

### Resonator Structure: Seventh Example

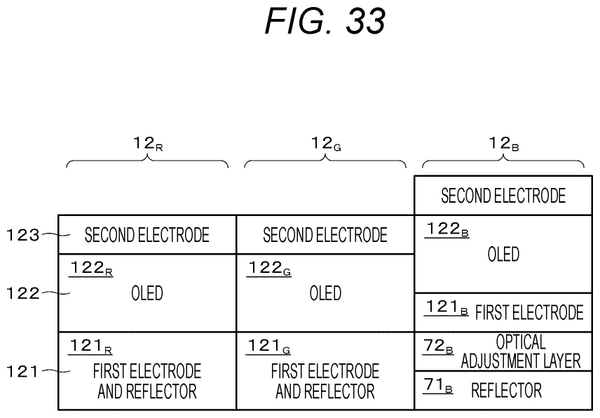

FIG. 33 is a schematic cross-sectional view for explaining a seventh example of the resonator structure.

In the seventh example, basically, the sixth example is applied to the light emitting elements 12_{R} and 12_{G}, and the first example is applied to the light emitting element 12_{B}. Also in this configuration, it is possible to set an optical distance that causes optimum resonance for the wavelength of light according to the color to be displayed.

The first electrodes (also serving as reflectors) 121_{R} and 121_{G} used for the light emitting elements 12_{R} and 12_{G} can be constituted by a single metal such as aluminum (Al), silver (Ag), gold (Au), or copper (Cu), or an alloy containing these as a main component.

Materials and the like constituting the reflector 71B, the optical adjustment layer 72B, and the first electrode 121B used for the light emitting element 12B are similar to the contents described in the first example, and thus description thereof is omitted.

### 8 Application Example

### Electronic Device

The display apparatus 101 and the like according to the first embodiment may be provided in various electronic devices. The display apparatus 101 and the like according to the first embodiment are particularly required to have high resolution such as an eyewear device such as a head-mounted display or an electronic view finder of a video camera or a single-lens reflex camera, and are suitable for those that are enlarged and used near eyes.

### Specific Example 1

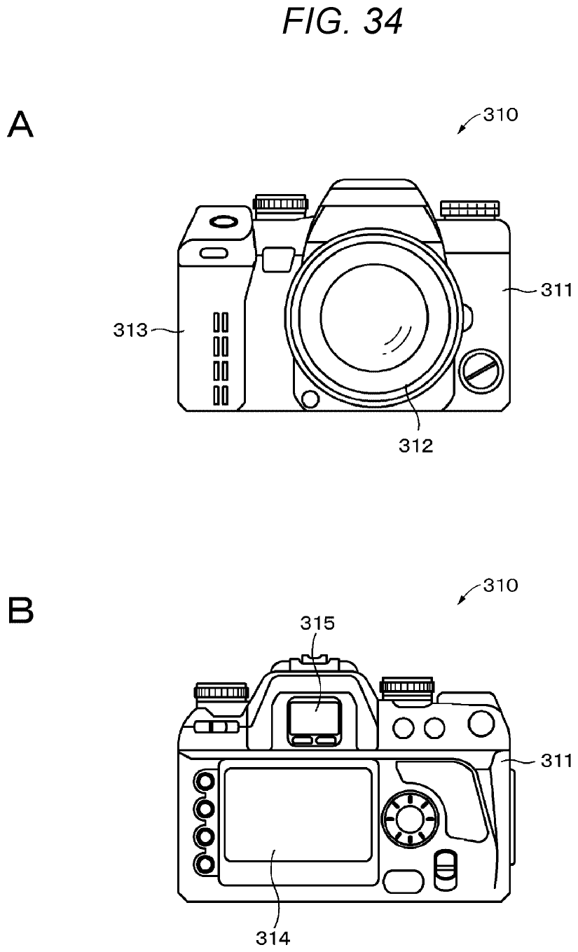

FIGS. 34A and 34B illustrate an example of an external appearance of digital still camera 310. The digital still camera 310 is of a lens interchangeable single-lens reflex type, and includes an interchangeable imaging lens unit (interchangeable lens) 312 substantially at the center of the front of the camera main body portion (camera body) 311, and a grip portion 313 to be held by a person who captures an image on the front left side.

A monitor 314 is provided at a position shifted to the left from the center of the back surface of the camera main body portion 311. An electronic view finder (eyepiece window) 315 is provided above the monitor 314. By looking into the electronic view finder 315, the person who captures an image can determine composition by visually recognizing the optical image of a subject guided from the imaging lens unit 312. The electronic view finder 315 includes any of the display apparatuses 101 and the like according to the first embodiment.

### Specific Example 2

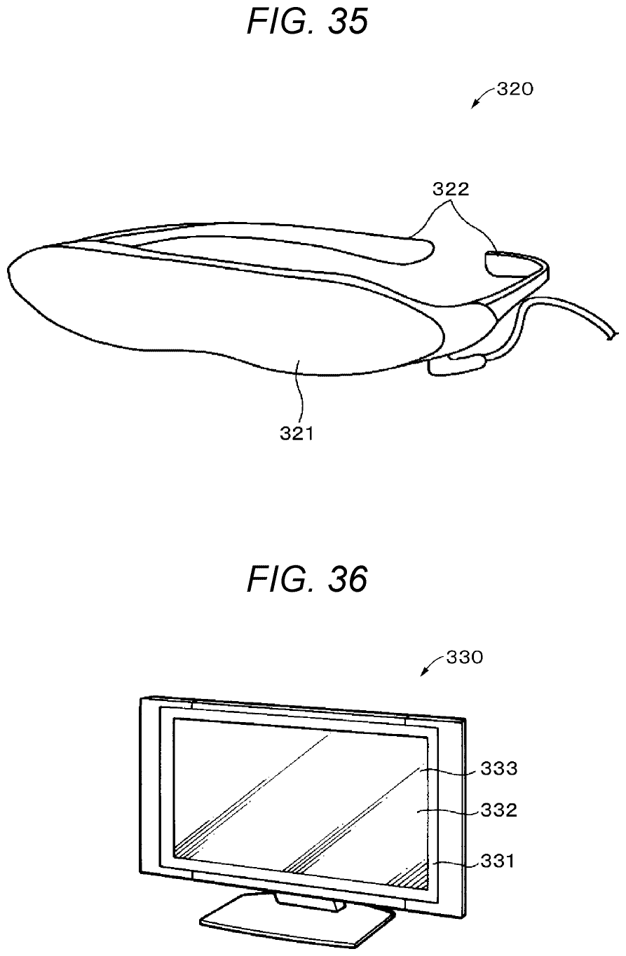

FIG. 35 illustrates an example of an appearance of a head-mounted display 320. The head-mounted display 320 is an example of an eyewear device. The head-mounted display 320 includes, for example, ear hooking portions 322 to be worn on the head of the user on both sides of the eyeglass-shaped display section 321. The display section 321 includes any one of the display apparatus 101 and the like according to the first embodiment.

### Specific Example 3

FIG. 36 illustrates an example of an external appearance of a television apparatus 330. The television apparatus 330 includes, for example, a video display screen section 331 including a front panel 332 and a filter glass 333, and the video display screen section 331 includes any one of the display apparatuses 101 according to the first embodiment and the like.

### Specific Example 4

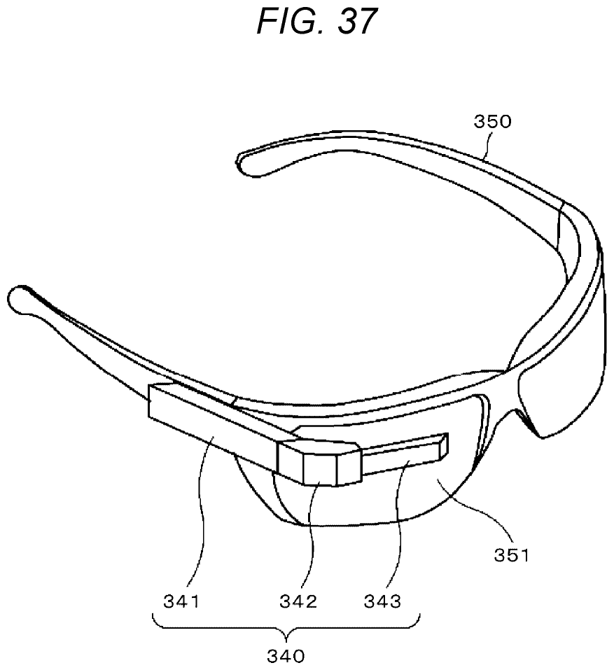

FIG. 37 illustrates an example of an appearance of a see-through head-mounted display 340. The see-through head-mounted display 340 is an example of an eyewear device. The see-through head-mounted display 340 includes a main body portion 341, an arm 342, and a lens barrel 343.

The main body portion 341 is connected to the arm 342 and glasses 350. Specifically, an end portion of the main body portion 341 in the long side direction is coupled to the arm 342, and one side of the side surface of the main body portion 341 is coupled to the glasses 350 via a connection member. Note that the main body portion 341 may be directly mounted on the head of the human body.

The main body portion 341 incorporates a control board for controlling the operation of the see-through head-mounted display 340 and a display section. The arm 342 connects the main body portion 341 and the lens barrel 343 and supports the lens barrel 343. Specifically, the arm 342 is coupled to the end portion of the main body portion 341 and the end portion of the lens barrel 343, and fixes the lens barrel 343. Furthermore, the arm 342 incorporates a signal line for communicating data related to an image provided from the main body portion 341 to the lens barrel 343.

The lens barrel 343 projects image light provided from the main body portion 341 via the arm 342 toward the eyes of the user wearing the see-through head-mounted display 340 through the eyepiece 351. In the see-through head-mounted display 340, the display section of the main body portion 341 includes any one of the display apparatuses 101 according to the first embodiment and the like.

### Specific Example 5

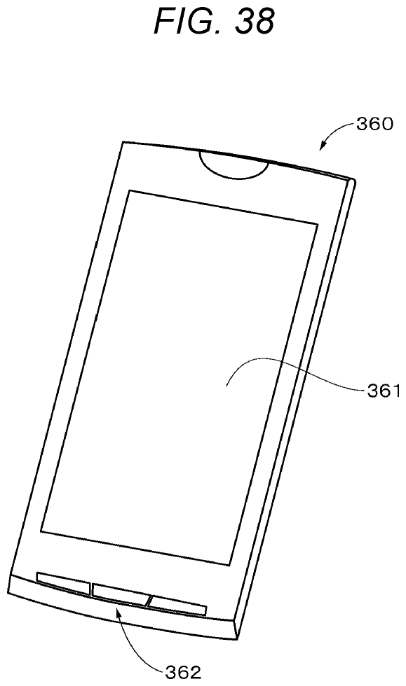

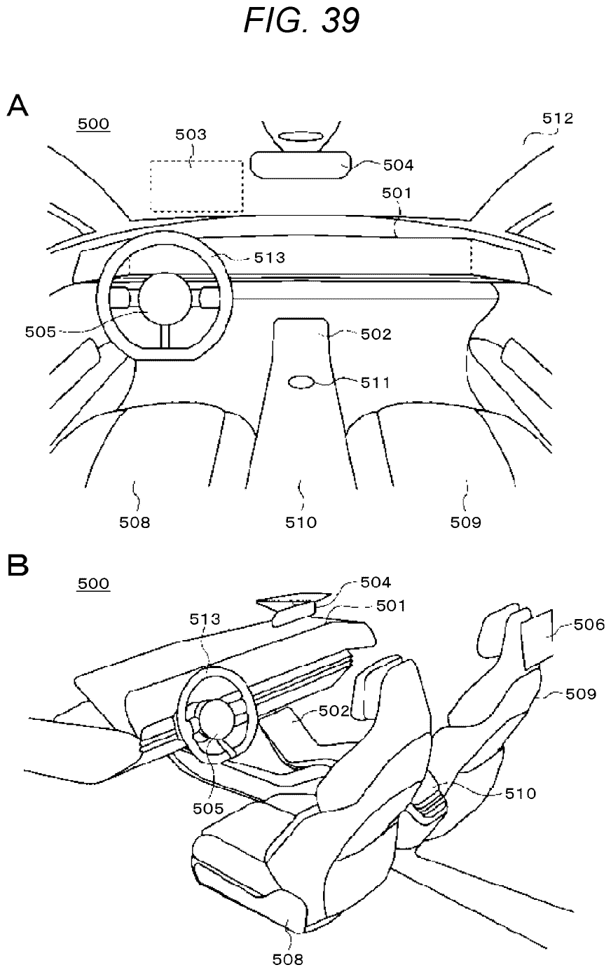

FIG. 38 illustrates an example of an external appearance of a smartphone 360. The smartphone 360 includes a display section 361 for displaying various types of information, an operation section 362 including a button for receiving an operation input by the user, and the like. The display section 361 includes any one of the display apparatus 101 and the like according to the first embodiment.

### Specific Example 6

The display apparatus 101 and the like according to the first embodiment may be provided in various displays provided in the vehicle.

FIGS. 39A and 39B are diagrams illustrating an example of an internal configuration of a vehicle 500 provided with various displays. Specifically, FIG. 39A is a diagram illustrating an example of an internal state of the vehicle 500 from the rear to the front of the vehicle 500, and FIG. 39B is a diagram illustrating an example of an internal state of the vehicle 500 from the oblique rear to the oblique front of the vehicle 500.

The vehicle 500 includes a center display 501, a console display 502, a head-up display 503, a digital rear mirror 504, a steering wheel display 505, and a rear entertainment display 506. At least one of these displays includes any one of the display apparatus 101 and the like according to the first embodiment. For example, all of these displays may include any of the display apparatuses 101 and the like according to the first embodiment.

The center display 501 is disposed on a dashboard portion facing the driver's seat 508 and the passenger seat 509. FIGS. 39A and 39B illustrate an example of the center display 501 having a horizontally long shape extending from the driver's seat 508 side to the passenger seat 509 side, but the screen size and the arrangement place of the center display 501 are arbitrary. The center display 501 can display information detected by various sensors. As a specific example, the center display 501 can display a captured image captured by the image sensor, a distance image to an obstacle in front of or on a side of the vehicle 500 measured by the ToF sensor, a passenger's body temperature detected by the infrared sensor, and the like. The center display 501 can be used to display, for example, at least one of safety-related information, operation-related information, a lifelog, health-related information, authentication/identification-related information, or entertainment-related information.

The safety-related information is information about doze sensing, looking-away sensing, sensing of mischief of a child riding together, presence or absence of wearing of a seat belt, sensing of leaving of an occupant, and the like, and is information sensed by a sensor disposed in an overlapping manner on the back surface side of the center display 501, for example. The operation-related information detects a gesture related to the operation of the occupant using the sensor. The sensed gestures may include operation of various equipment in the vehicle 500. For example, operations of air conditioning equipment, a navigation apparatus, an AV apparatus, a lighting apparatus, and the like are detected. The lifelog includes lifelogs of all the occupants. For example, the lifelog includes an action record of each occupant in the vehicle. By acquiring and storing the lifelog, it is possible to check the state of the occupant at the time of the accident. The health-related information detects the body temperature of the occupant using a sensor such as a temperature sensor, and estimates the health condition of the occupant on the basis of the detected body temperature. Alternatively, the face of the occupant may be imaged using an image sensor, and the health condition of the occupant may be estimated from the imaged facial expression. Furthermore, a conversation may be made with the occupant in an automatic voice, and the health condition of the occupant may be estimated on the basis of the answer content of the occupant. The authentication/identification-related information includes a keyless entry function of performing face authentication using a sensor, an automatic adjustment function of a sheet height and a position in face identification, and the like. The entertainment-related information includes a function of detecting operation information of the AV apparatus by an occupant using the sensor, a function of recognizing the face of an occupant by the sensor and providing content suitable for the occupant by the AV apparatus, and the like.

The console display 502 can be used to display the lifelog information, for example. The console display 502 is disposed near a shift lever 511 of a center console 510 between the driver's seat 508 and the passenger seat 509. The console display 502 can also display information detected by various sensors. In addition, the console display 502 may display an image of the periphery of the vehicle captured by the image sensor, or may display a distance image to an obstacle in the periphery of the vehicle.

The head-up display 503 is virtually displayed behind a windshield 512 in front of the driver's seat 508. The head-up display 503 can be used to display at least one of the safety-related information, the operation-related information, the lifelog, the health-related information, the authentication/identification-related information, or the entertainment-related information, for example. Since the head-up display 503 is virtually arranged in front of the driver's seat 508 in many cases, it is suitable for displaying information directly related to the operation of the vehicle 500 such as a speed of the vehicle 500 and a remaining amount of fuel (battery).

The digital rear mirror 504 can not only display the rear of the vehicle 500 but also display the state of the occupant in the rear seat, and thus can be used to display the lifelog information, for example, by disposing the sensor to be superimposed on the back surface side of the digital rear mirror 504.

The steering wheel display 505 is disposed near the center of the steering wheel 513 of the vehicle 500. The steering wheel display 505 can be used to display at least one of the safety-related information, the operation-related information, the lifelog, the health-related information, the authentication/identification-related information, or the entertainment-related information, for example. In particular, since the steering wheel display 505 is close to the driver's hand, it is suitable for displaying lifelog information such as the body temperature of the driver, or for displaying information regarding the operation of an AV apparatus, an air conditioning equipment, or the like.

The rear entertainment display 506 is attached to the back side of the driver's seat 508 and the passenger seat 509, and is for viewing by an occupant in the rear seat. The rear entertainment display 506 can be used to display, for example, at least one of the safety-related information, the operation-related information, the lifelog, the health-related information, the authentication/identification-related information, or the entertainment-related information. In particular, because the rear entertainment display 506 is in front of the occupant in the rear seat, information related to the occupant in the rear seat is displayed. For example, information regarding the operation of the AV apparatus or the air conditioning equipment may be displayed, or a result of measurement of the body temperature or the like of the occupant in the rear seat with a temperature sensor may be displayed on the display.

A sensor may be disposed on the back surface side of a display apparatus 101 and the like in an overlapping manner, so that the distance to an object present in the surroundings can be measured in the configuration. Optical distance measurement methods are roughly classified into a passive type and an active type. The passive type measures a distance by receiving light from an object without projecting light from a sensor to the object. The passive type includes a lens focus method, a stereo method, a monocular vision method, and the like. In the active type, light is projected onto an object, and reflected light from the object is received by a sensor to measure a distance. Methods of the active type include an optical radar method, an active stereo method, an illuminance difference stereo method, a moire topography method, an interference method, and the like. The display apparatus 101 and the like according to the first embodiment can be applied to any of these types of distance measurement. With a sensor arranged on the back surface side of the above-described display apparatus 101 in an overlapping manner, distance measurement of the passive type or the active type described above can be performed.

### REFERENCE SIGNS LIST

10R, 10G, 10B Subpixel (first pixel, second pixel, or third pixel)
11 Drive substrate
111 Pad portion
12R, 12G, 12B Light emitting element (first light emitting element or second light emitting element)
121 First electrode
122 OLED layer
123 Second electrode
13 Protective layer
14 Planarization layer
15 Color filter
15R Filter portion (first filter portion or third filter portion)
15G Filter portion (first filter portion or third filter portion)
15B Filter portion (first filter portion or third filter portion)
150, 151, 152 Filter portion (second filter portion or fourth filter portion)
150a Filter portion (fifth filter portion)
16 Lens array
161 Lens
101, 102 Display apparatus
310 Digital still camera
320 Head-mounted display
330 Television apparatus
340 See-through head-mounted display
360 Smartphone
500 Vehicle
RE1 Effective pixel region
RE2 Peripheral region

1. A display apparatus comprising:
a plurality of first pixels capable of emitting light of a first color; and
a plurality of second pixels capable of emitting light of a second color,
wherein
the plurality of second pixels constitutes a plurality of columns, and
a column of the second pixels includes:
a plurality of first light emitting elements arranged in a column direction of a column of the second pixels;
a first filter portion provided above the plurality of first light emitting elements and having the second color; and
a plurality of second filter portions provided above the plurality of first light emitting elements and at respective boundary portions between the second pixels adjacent in the column direction, the plurality of second filter portions having a color different from the second color.

2. The display apparatus according to claim 1, wherein
the second filter portion is provided on the first filter portion.

3. The display apparatus according to claim 1, wherein
the second filter portion is provided in the first filter portion.

4. The display apparatus according to claim 3, wherein
a thickness of the second filter portion is substantially same as a thickness of the first filter portion.

5. The display apparatus according to claim 3, wherein
the first filter portion has a surface on a side opposite to a side of the first light emitting element, and
a part of the second filter portion protrudes on the surface of the first filter portion.

6. The display apparatus according to claim 3, wherein
the first filter portion covers the second filter portion.

7. The display apparatus according to claim 1, wherein
the column of the second pixels further includes a plurality of lenses provided above the plurality of first light emitting elements.

8. The display apparatus according to claim 1, wherein
at least a part of the plurality of second filter portions is shifted in an in-plane direction with reference to the first light emitting element.

9. The display apparatus according to claim 1, wherein
a size of the second pixel in the column direction is larger than a size of the first pixel in the column direction.

10. The display apparatus according to claim 1, wherein
the first color includes red, and
the first pixel has a resonator structure.

11. The display apparatus according to claim 1, further comprising
a plurality of third pixels capable of emitting light of a third color.

12. The display apparatus according to claim 11, wherein
the second filter portion has the first color or the third color.

13. The display apparatus according to claim 11, wherein
the first color, the second color, and the third color are different from each other,
the first color, the second color, and the third color are each one color selected from a group including red, blue, and green, and
tristimulus values X, Y, and Z of the CIE1931 color system obtained by measuring a white image displayed on the display apparatus from the column direction are substantially equal.

14. The display apparatus according to claim 11, wherein
the plurality of third pixels constitutes a plurality of columns, and
a column of the third pixels includes:
a plurality of second light emitting elements arranged in the column direction;
a third filter portion provided above the plurality of second light emitting elements and having the third color; and
a plurality of fourth filter portions provided above the plurality of second light emitting elements and at respective boundary portions between the third pixels adjacent in the column direction, the plurality of fourth filter portions having a color different from the third color.

15. The display apparatus according to claim 11, wherein
the first pixel, the second pixel, and the third pixel are arranged in a stripe array.

16. The display apparatus according to claim 11, wherein
the first pixel, the second pixel, and the third pixel are arranged in a square array, and
the second pixel is arranged adjacent to the first pixel and the third pixel.

17. The display apparatus according to claim 1, wherein
the column of the second pixels further includes a fifth filter portion provided in the second pixel in plan view and having a color different from the second color.

18. The display apparatus according to claim 1, wherein
the plurality of first light emitting elements is configured to emit white light or light of the second color.

19. A display apparatus comprising:
a plurality of first pixels capable of emitting light of a first color; and
a plurality of second pixels capable of emitting light of a second color,
wherein
the plurality of second pixels constitutes a plurality of columns, and
a column of the second pixels includes:
a plurality of first light emitting elements arranged in a column direction of a column of the second pixels;
a color conversion section provided above the plurality of first light emitting elements and capable of converting light emitted from the plurality of first light emitting elements into light of the second color; and
a plurality of filter portions provided above the plurality of first light emitting elements and at respective boundary portions between the second pixels adjacent in the column direction, the plurality of filter portions having a color different from the second color.

20. An electronic device comprising the display apparatus according to claim 1.
